(19) United States
(12) Patent Application Publication
(10) Pub. No.: US 2024/0194459 A1
(43) Pub. Date: Jun. 13, 2024

(54) PROCESSING METHOD AND PLASMA PROCESSING APPARATUS

(71) Applicant: Tokyo Electron Limited, Tokyo (JP)

(72) Inventors: Kazuya NAGASEKI, Miyagi (JP); Kazuki MOYAMA, Miyagi (JP); Shinji HIMORI, Miyagi (JP); Masanobu HONDA, Miyagi (JP); Satoru TERUUCHI, Miyagi (JP)

(73) Assignee: Tokyo Electron Limited, Tokyo (JP)

(21) Appl. No.: 18/416,880

(22) Filed: Jan. 18, 2024

Related U.S. Application Data
(63) Continuation of application No. PCT/JP2022/029016, filed on Jul. 27, 2022.

(30) Foreign Application Priority Data
Aug. 3, 2021 (JP) 2021-127619

(51) Int. Cl. H01J 37/32

(52) U.S. Cl. CPC H01J 37/32724

(57) ABSTRACT

A processing method and corresponding device for performing plasma processing on a substrate includes placing a temperature adjustment target onto a support surface of a substrate support in a processing chamber being decompressible, forming a heat transfer layer for the temperature adjustment target on the support surface of the substrate support, and performing plasma processing on the substrate on the support surface on which the heat transfer layer is formed. The heat transfer layer is deformable and includes at least one of a liquid layer or a deformable solid layer.

### CROSS-REFERENCE TO RELATED APPLICATIONS

This is a continuation application of PCT/JP2022/029016, filed on Jul. 27, 2022, designating the United States of America, which is based on and claims priority to Japanese Patent Application No. JP 2021-127619 filed on Aug. 3, 2021. The entire contents of the above-identified applications, including the specifications, drawings and claims, are incorporated herein by reference in their entirety.

### FIELD

The present disclosure relates to a processing method and a plasma processing apparatus.

### BACKGROUND

Patent Literature 1 describes a substrate processing apparatus including a substrate support having a support surface on which a substrate is placeable and including a gas supply line for supplying a heat transfer gas to a clearance between the substrate and the support surface.

### CITATION LIST

### Patent Literature

Patent Literature 1: Japanese Unexamined Patent Application Publication No. 2020-120081

### BRIEF SUMMARY

### Technical Problem

The technique according to the present disclosure efficiently adjusts the temperature of a temperature adjustment target during plasma processing.

### Solution to Problem

A processing method for performing plasma processing on a substrate according to an aspect of the present disclosure includes placing a temperature adjustment target onto a support surface of a substrate support in a processing chamber being decompressible, forming a heat transfer layer for the temperature adjustment target on the support surface of the substrate support, and performing plasma processing on the substrate on the support surface on which the heat transfer layer is formed. The heat transfer layer is deformable and includes at least one of a liquid layer or a deformable solid layer.

### Advantageous Effects

The technique according to the above aspect of the present disclosure can efficiently

adjust the temperature of a temperature adjustment target during plasma processing.

### BRIEF DESCRIPTION OF DRAWINGS

FIG. 1 is a schematic plan view of a plasma processing system including a processing module as a plasma processing apparatus according to a first embodiment.

FIG. 2 is a schematic longitudinal cross-sectional view of the processing module as the plasma processing apparatus according to the first embodiment.

FIG. 3 is a flowchart of example wafer processing performed in the processing module in FIG. 2.

FIG. 4 is a diagram of the processing module in FIG. 2 in a processing state during the wafer processing.

FIG. 5 is a diagram of the processing module in FIG. 2 in a processing state during the wafer processing.

FIG. 6 is a diagram of the processing module in FIG. 2 in a processing state during the wafer processing.

FIG. 7 is a diagram of the processing module in FIG. 2 in a processing state during the wafer processing.

FIG. 8 is a diagram of the processing module in FIG. 2 in a processing state during the wafer processing.

FIG. 9 is a diagram describing another example of raw gas supply.

FIG. 10 is a diagram describing another example of raw gas supply.

FIG. 11 is a diagram describing another example of raw gas supply.

FIG. 12 is a diagram describing another example of raw gas supply.

FIG. 13 is a diagram of the processing chamber in another example state in forming a heat transfer layer.

FIG. 14 is a schematic longitudinal cross-sectional view of a processing module as a plasma processing apparatus according to a second embodiment.

FIG. 15 is a flowchart of example wafer processing performed in the processing module in FIG. 14.

FIG. 16 is a diagram of the processing module in FIG. 14 in a processing state during the wafer processing.

FIG. 17 is a diagram of the processing module in FIG. 14 in a processing state during the wafer processing.

FIG. 18 is a diagram of the processing module in FIG. 14 in a processing state during the wafer processing.

FIG. 19 is a diagram of the processing module in FIG. 14 in a processing state during the wafer processing.

FIG. 20 is a diagram of a specific example of grooves.

FIG. 21 is a diagram of the specific example of the grooves.

FIG. 22 is a schematic longitudinal cross-sectional view of a processing module as a plasma processing apparatus according to a third embodiment.

FIG. 23 is a schematic longitudinal cross-sectional view of a processing module as a plasma processing apparatus according to a fourth embodiment.

FIG. 24 is a schematic plan view of a plasma processing system including a processing module as a plasma processing apparatus according to a fifth embodiment.

FIG. 25 is a schematic longitudinal cross-sectional view of the processing module as the plasma processing apparatus according to the fifth embodiment.

FIG. 26 is a flowchart of example wafer processing performed in the processing module in FIG. 25.

FIG. 27 is a diagram of the processing module in FIG. 25 in a processing state during the wafer processing.

FIG. 28 is a diagram of the processing module in FIG. 25 in a processing state during the wafer processing.

FIG. 29 is a diagram of the processing module in FIG. 25 in a processing state during the wafer processing.

FIG. 30 is a diagram of the processing module in FIG. 25 in a processing state during the wafer processing.

FIG. 31 is a schematic longitudinal cross-sectional view of a processing module as a plasma processing apparatus according to a sixth embodiment.

FIG. 32 is a schematic longitudinal cross-sectional view of the processing module as the plasma processing apparatus according to the sixth embodiment.

FIG. 33 is a flowchart of example wafer processing performed in the processing module in FIGS. 31 and 32.

FIG. 34 is a diagram of the processing module in FIGS. 31 and 32 in a processing state during the wafer processing.

FIG. 35 is a diagram of the processing module in FIGS. 31 and 32 in a processing state during the wafer processing.

FIG. 36 is a diagram of the processing module in FIGS. 31 and 32 in a processing state during the wafer processing.

### DETAILED DESCRIPTION

In the manufacturing process for semiconductor devices or other devices, plasma processing such as etching or film deposition is performed on substrates including semiconductor wafers (hereafter referred to as wafers) using plasma. Plasma processing is performed on a substrate placed on a substrate support in a decompressed processing chamber.

To achieve intended and uniform plasma processing between the center and the periphery of the substrate, an annular member as viewed in plan or an edge ring may be placed on the substrate support to surround the substrate on the substrate support.

The results of plasma processing depend on the temperature of the substrate. The temperature of the substrate support is adjusted during plasma processing, thus allowing the temperature of the substrate to be adjusted through the substrate support.

When the edge ring described above is used, the temperature of the edge ring also affects the results of plasma processing at the periphery of the substrate. The temperature of the edge ring is thus also to be adjusted. The temperature of the edge ring is also adjusted through the substrate support.

To efficiently adjust the temperature of the substrate and the edge ring through the substrate support, a heat transfer gas, such as a He gas, is supplied to between the substrate support and the substrate and between the substrate support and the edge ring in a known structure.

However, when a large amount of heat is input from the plasma to the substrate during plasma processing, the temperature of at least either the substrate or the edge ring may not be fully adjusted using a heat transfer gas as described above.

The technique according to one or more aspects of the present disclosure efficiently adjusts the temperature of at least either the substrate or the edge ring as a temperature adjustment target during plasma processing.

The processing method and the plasma processing apparatus according to the present embodiments will now be described with reference to the drawings. The same reference numerals denote components having substantially the same functions herein and in the drawings, and such components will not be described repeatedly.

### First Embodiment

### Plasma Processing System

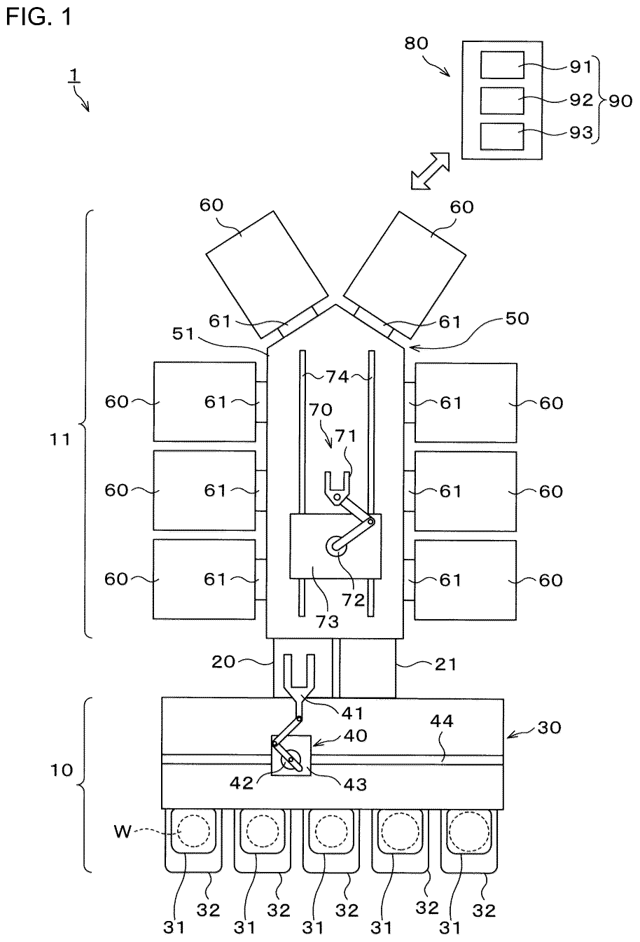

FIG. 1 is a schematic plan view of a plasma processing system including a processing module as a plasma processing apparatus according to a first embodiment.

The plasma processing system 1 in FIG. 1 includes an atmospheric unit 10 and a decompressor 11, which are connected together with loadlock modules 20 and 21 in between. The atmospheric unit 10 includes an atmospheric module in which intended processing is performed on a wafer W as a substrate under an atmospheric pressure. The decompressor 11 includes processing modules 60 in which intended processing is performed on the wafer W under a decompressed atmosphere (vacuum atmosphere).

The loadlock modules 20 and 21 connect a loader module 30 included in the atmospheric unit 10 and a transfer module 50 included in the decompressor 11 with a gate valve (not shown). The loadlock modules 20 and 21 temporarily hold the wafer W. The loadlock modules 20 and 21 can switch their internal spaces between the atmospheric pressure and the decompressed atmosphere.

The atmospheric unit 10 includes the loader module 30 including a transferer 40 (described later) and load ports 32 to receive front-opening unified pods (FOUP) 31. Each FOUP 31 can store multiple wafers W. The loader module 30 may be connected to an orienter module (not shown) that adjusts the horizontal orientation of a wafer W and a buffer module (not shown) that temporarily stores multiple wafers W.

The loader module 30 includes a rectangular housing with an internal space maintained at the atmospheric pressure. The multiple load ports 32, for example, five load ports 32, are aligned in one side surface, which is a long side of the housing of the loader module 30. The loadlock modules 20 and 21 are aligned on the other side surface, which is another long side of the housing of the loader module 30.

The transferer 40 for transferring a wafer W is located in the housing of the loader module 30. The transferer 40 includes a transfer arm 41 that supports a wafer W during transfer, a rotary stand 42 supporting the transfer arm 41 in a rotatable manner, and a base 43 receiving the rotary stand 42. The loader module 30 includes a guide rail 44 extending in the longitudinal direction of the loader module 30. The base 43 is located on the guide rail 44, along which the transferer 40 is movable.

The decompressor 11 includes the transfer module 50 that transfers the wafers W and the processing modules 60 as plasma processing apparatuses that perform plasma processing on the wafers W transferred from the transfer module 50. The internal spaces of the transfer module 50 and the processing modules 60 (more specifically, the internal spaces of a decompressed transfer chamber 51 and a plasma processing chamber 100 described later) are maintained in the decompressed atmosphere. The single transfer module 50 receives multiple (e.g., eight) processing modules 60.

The transfer module 50 includes the decompressed transfer chamber 51 defined by a polygonal (pentagonal in the illustrated example) housing. The decompressed transfer chamber 51 is connected to the loadlock modules 20 and 21. The transfer module 50 transfers a wafer W loaded into the loadlock module 20 to one processing module 60, and unloads a wafer W on which intended plasma processing is performed in the processing module 60 to the atmospheric unit 10 through the loadlock module 21.

The processing module 60 performs plasma processing such as etching or film deposition on a wafer W. The processing module 60 is connected to the transfer module 50 with a gate valve 61. The structure of the processing module 60 will be described later.

A transferer 70 for transferring a wafer W is located in the decompressed transfer chamber 51 in the transfer module 50. The transferer 70 includes, similarly to the transferer 40 described above, a transfer arm 71 that supports a wafer W during transfer, a rotary stand 72 supporting the transfer arm 71 in a rotatable manner, and a base 73 receiving the rotary stand 72. The transfer module 50 includes guide rails 74 extending in the longitudinal direction of the transfer module 50 in the decompressed transfer chamber 51. The base 73 is located on the guide rails 74, along which the transferer 70 is movable.

In the transfer module 50, the transfer arm 71 receives a wafer W held in the loadlock module 20 and loads the wafer W into the processing module 60. The transfer arm 71 also receives a wafer held in the processing module 60 and transfers the wafer to the loadlock module 21.

The plasma processing system 1 further includes a controller 80. In one embodiment, the controller 80 processes computer-executable instructions that cause the plasma processing system 1 to perform various steps described in one or more aspects of the present disclosure. The controller 80 may control the other components of the plasma processing system 1 to perform various steps described herein. In one embodiment, some or all of the components of the controller 80 may be included in the other components of the plasma processing system 1. In one embodiment, the controller 80 also processes computer-executable instructions that cause the processing module 60 to perform various steps described in one or more aspects of the present disclosure. The controller 80 may control the other components of the processing module 60 to perform various steps described herein. In one embodiment, some or all of the components of the controller 80 may be included in the other components of the processing module 60. The controller 80 may include, for example, a computer 90. The computer 90 may include, for example, a processor (central processing unit or CPU) 91, a storage 92, and a communication interface 93. The CPU 91 may perform various control operations based on programs stored in the storage 92. The storage 92 may include a random-access memory (RAM), a read-only memory (ROM), a hard disk drive (HDD), a solid-state drive (SSD), or a combination of these. The communication interface 93 may communicate with the other components of the plasma processing system 1 through a communication line such as a local area network (LAN).

Wafer Processing with Plasma Processing System 1

The wafer processing performed in the plasma processing system 1 described above will now be described.

First, a wafer W is removed from an intended FOUP 31 with the transferer 40 and loaded into the loadlock module 20. The loadlock module 20 is then sealed and decompressed. The internal space of the loadlock module 20 is then connected with the internal space of the transfer module 50.

The wafer W is then held by the transferer 70 and transferred from the loadlock module 20 to the transfer module 50.

The wafer W is then loaded into an intended processing module 60 by the transferer 70 through the corresponding gate valve 61 that is open. The gate valve 61 is then closed and intended processing is performed on the wafer W in the processing module 60. The processing performed on the wafer W in the processing module 60 will be described later.

The gate valve 61 is then opened, and the wafer W is unloaded from the processing module 60 by the transferer 70. The gate valve 61 is then closed.

The wafer W is then loaded into the loadlock module 21 by the transferer 70. In response to the wafer W being loaded into the loadlock module 21, the loadlock module 21 is sealed and vented to the atmosphere. The internal space of the loadlock module 21 is then connected with the internal space of the loader module 30.

The wafer W is held by the transferer 40 and returned from the loadlock module 21 through the loader module 30 to an intended FOUP 31 for storage. This completes the wafer processing in the plasma processing system 1.

### Processing Module 60

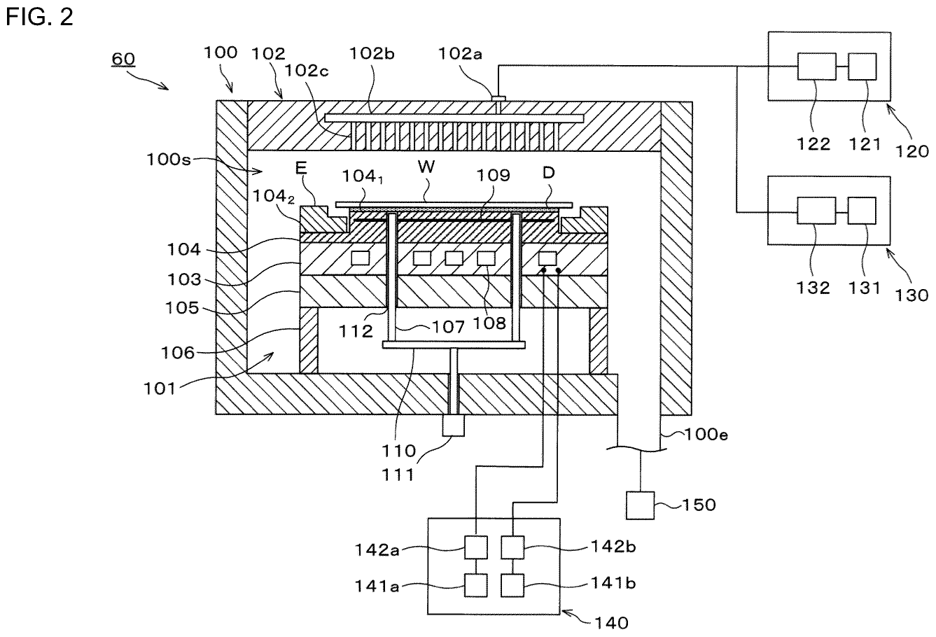

The processing module 60 will now be described with reference to FIG. 2. FIG. 2 is a schematic longitudinal cross-sectional view of the processing module 60.

As shown in FIG. 2, the processing module 60 includes a plasma processing chamber 100 as a processing chamber, gas supply units 120 and 130, a radio-frequency (RF) power supply unit 140, and an exhaust system 150. The processing module 60 further includes a wafer support 101 as a substrate support and an upper electrode 102.

The wafer support 101 is located in a lower area in a plasma processing space 100s in the plasma processing chamber 100, which is decompressible. The upper electrode 102 is located above the wafer support 101. The upper electrode 102 may serve as a part of a wall defining the plasma processing space 100s, or more specifically, as a part of the ceiling of the plasma processing chamber 100.

The wafer support 101 can support a wafer W in the plasma processing space 100s. In one embodiment, the wafer support 101 includes a lower electrode 103, an electrostatic chuck (ESC) 104, an insulator 105, legs 106, and lifters 107. The wafer support 101 further includes a temperature adjuster to adjust the temperature (e.g., the temperature of an upper surface 104₁ in a center portion) of the ESC 104. The temperature adjuster includes, for example, a heater, a channel, or a combination of these. The channel allows a temperature adjusting fluid such as a refrigerant or a heat transfer gas to flow.

The lower electrode 103 is formed from, for example, a conductive material such as aluminum and is fixed to the insulator 105. In one embodiment, a channel 108 for the temperature adjusting fluid is located inside the lower electrode 103. The channel 108 is a part of the temperature adjuster. The channel 108 receives a temperature adjusting fluid from, for example, a chiller unit (not shown) located outside the plasma processing chamber 100. The temperature adjusting fluid supplied to the channel 108 returns to the chiller unit. For example, the ESC 104, a wafer W placed on the ESC 104, and an edge ring E can be cooled to a predetermined temperature with low-temperature brine as a temperature adjusting fluid circulating through the channel 108. For example, the ESC 104, the wafer W placed on the ESC 104, and the edge ring E can also be heated to a predetermined temperature with high-temperature brine as a temperature adjusting fluid circulating in the channel 108.

The ESC 104 placed on the lower electrode 103 can electrostatically clamp the wafer W with an electrostatic force. In one embodiment, the ESC 104 has a central upper surface higher than a peripheral upper surface. The ESC 104 has the central upper surface 104₁ serving as a wafer support surface on which the wafer W is placeable and a peripheral upper surface 104₂ serving as a ring support surface on which the edge ring E is placeable. The edge ring E is an annular member as viewed in plan and is located adjacent to the wafer W to surround the wafer W placed on the central upper surface 104₁ of the ESC 104.

The ESC 104 is an example fastener that fastens the wafer W to the central upper surface 104₁ of the ESC 104, or more specifically, to the wafer support surface. An electrode 109 is located in a center portion of the ESC 104.

The electrode 109 receives a direct current (DC) voltage from a DC power supply (not shown). This generates an electrostatic force for electrostatically clamping the wafer W onto the central upper surface 104₁ of the ESC 104.

In one embodiment, the ESC 104 can also electrostatically clamp the edge ring E with an electrostatic force. The ESC 104 includes an electrode (not shown) to electrostatically clamp the edge ring E onto the wafer support 101.

In one embodiment, the peripheral upper surface 104₂ of the ESC 104 has a gas supply hole (not shown) for supplying a heat transfer gas such as a He gas to the back surface of the edge ring E on the peripheral upper surface 104₂. The heat transfer gas from a gas supply unit (not shown) is supplied through the gas supply hole. The gas supply unit may include one or more gas sources and one or more pressure controllers. In one embodiment, the gas supply unit supplies, for example, the heat transfer gas from the gas source(s) to the gas supply hole with the pressure controller(s).

The center portion of the ESC 104 has, for example, a smaller diameter than the wafer W. The wafer W placed on the central upper surface (hereafter referred to as a wafer support surface) 104₁ of the ESC 104 thus has its periphery protruding from the center portion of the ESC 104.

The edge ring E has, for example, a step in its upper portion. The edge ring E thus has an upper surface of its outer periphery higher than the upper surface of its inner periphery. The inner periphery of the edge ring E is located under the periphery of the wafer W protruding from the center portion of the ESC 104.

A heater (or more specifically, a heating resistor) included in the temperature adjuster may be located inside the ESC 104. The ESC 104 and the wafer W placed on the ESC 104 can be heated to a predetermined temperature with the heater energized. In this case, the ESC 104 includes, for example, the electrode 109 for electrostatically clamping the wafer and the electrode for electrostatically clamping the edge ring between insulators and includes the heater buried inside the ESC 104.

The center portion of the ESC 104 including the electrode 109 for electrostatically clamping the wafer and the periphery of the ESC 104 including the electrode for electrostatically clamping the edge ring may be integral or separate from each other.

The insulator 105 is a disk of a ceramic material or another material, and the lower electrode 103 is fixed to the insulator 105. The insulator 105 has, for example, the same diameter as the lower electrode 103.

The legs 106 are cylinders of a ceramic material or another material supporting the ESC 104 with the lower electrode 103 and the insulator 105 in between. The legs 106 have, for example, an outer diameter equivalent to the outer diameter of the insulator 105 to support the periphery of the insulator 105.

Each lifter 107 is, for example, a cylindrical lifter that ascends and descends relative to the wafer support surface 104₁ of the ESC 104. When the lifter 107 ascends, its upper end protrudes from the wafer support surface 104₁ to support the wafer W. The lifters 107 allow transfer of the wafer W between the ESC 104 and the transfer arm 71 in the transferer 70.

Three or more lifters 107 spaced from one another extend in the vertical direction.

Each lifter 107 is connected to a support 110 supporting the lifter 107. The support 110 is connected to a drive 111 that generates a driving force to raise and lower the support 110 to raise and lower the multiple lifters 107. The drive 111 includes, for example, a motor (not shown) as a drive source to generate the driving force described above.

Each lifter 107 is placed through a through-hole 112 having the upper end that is open in the wafer support surface 104₁ of the ESC 104. The through-hole 112 extends through, for example, the center portion of the ESC 104, the lower electrode 103, and the insulator 105.

The lifters 107, the support 110, and the drive 111 are included in a lift assembly that raises and lowers the wafer W relative to the wafer support surface 104₁.

The above upper electrode 102 may serve as a shower head that supplies various gases from the gas supply units 120 and 130 into the plasma processing space 100s. In one embodiment, the upper electrode 102 includes a gas inlet 102a, a gas-diffusion compartment 102b, and multiple gas ports 102c. The gas inlet 102a allows passage of fluid between the gas supply units 120 and 130 and the gas-diffusion compartment 102b. The gas ports 102c allow passage of fluid between the gas-diffusion compartment 102b and the plasma processing space 100s. In one embodiment, the upper electrode 102 supplies various gases from the gas inlet 102a into the plasma processing space 100s through the gas-diffusion compartment 102b and the multiple gas ports 102c.

The gas supply unit 120 may include one or more gas sources 121 and one or more flow controllers 122. In one embodiment, the gas supply unit 120 supplies, for example, one or more gases (including a gas for removing a heat transfer layer D described later) from the respective gas sources 121 into the gas inlet 102a through the corresponding flow controllers 122. Each flow controller 122 may include, for example, a mass flow controller or a pressure-based flow controller. The gas supply unit 120 may further include one or more flow rate modulators that supply one or more process gases at a modulated flow rate or in a pulsed manner.

The gas supply unit 130 may include one or more gas sources 131 and one or more flow controllers 132. In one embodiment, the gas supply unit 130 supplies, for example, one or more gases including a raw gas for the heat transfer layer D (described later) from the respective gas sources 131 into the gas inlet 102a through the corresponding flow controllers 132. Each flow controller 132 may include, for example, a mass flow controller or a pressure-based flow controller. The gas supply unit 130 may further include one or more flow rate modulators that supply one or more gases for forming the heat transfer layer at a modulated flow rate or in a pulsed manner.

The heat transfer layer D being liquid is formed on, for example, the wafer support surface 104₁ of the wafer support 101 from a gas including the raw gas supplied from the gas supply unit 130. The gas supply unit 130 may thus serve as at least a part of a heat transfer layer forming unit to form the heat transfer layer D on the wafer support surface 104₁.

An RF power supply unit 140 provides RF power, or for example, one or more RF signals, to one or more electrodes, such as the lower electrode 103, the upper electrode 102, or both the lower electrode 103 and the upper electrode 102. This causes plasma to be generated from one or more process gases supplied into the plasma processing space 100s. The RF power supply unit 140 may thus serve as at least a part of a plasma generator for generating plasma from one or more process gases in the plasma processing chamber 100.

Plasma may be generated from one or more gases for forming the heat transfer layer supplied into the plasma processing space 100s with RF power provided from the RF power supply unit 140 as described above. The RF power supply unit 140 may thus serve as at least a part of a plasma generator for generating plasma from one or more gases including a raw gas in the plasma processing chamber 100.

The RF power supply unit 140 includes, for example, two RF generators 141a and 141b and two matching circuits 142a and 142b. In one embodiment, the RF power supply unit 140 provides a first RF signal from the first RF generator 141a through the first matching circuit 142a to the lower electrode 103. For example, the first RF signal may have a frequency of 27 to 100 MHz.

In one embodiment, the RF power supply unit 140 provides a second RF signal from the second RF generator 141b through the second matching circuit 142b to the lower electrode 103. For example, the second RF signal may have a frequency of 400 kHz to 13.56 MHz. Voltage pulses other than the RF may be provided in place of the second RF signal. The voltage pulses may be of a negative DC voltage. In some embodiments, the voltage pulses may be triangular wave pulses or impulses.

Although not illustrated, the present disclosure may be implemented in other embodiments. For example, in some embodiments, the RF power supply unit 140 may provide the first RF signal from an RF generator to the lower electrode 103, the second RF signal from another RF generator to the lower electrode 103, and a third RF signal from still another RF generator to the lower electrode 103. In some embodiments, the upper electrode 102 may receive a DC voltage.

In various embodiments, one or more RF signals (e.g., the first RF signal or the second RF signal) may have pulsed or modulated amplitudes. Such amplitude modulation may include pulse-amplitude modulation of an RF signal between an on-state and an off-state, or between two or more different on-states.

The exhaust system 150 may be connected to an outlet 100e in the bottom of the plasma processing chamber 100. The exhaust system 150 may include a pressure valve and a vacuum pump. The vacuum pump may include a turbomolecular pump, a roughing pump, or a combination of these.

### Wafer Processing in Processing Module 60

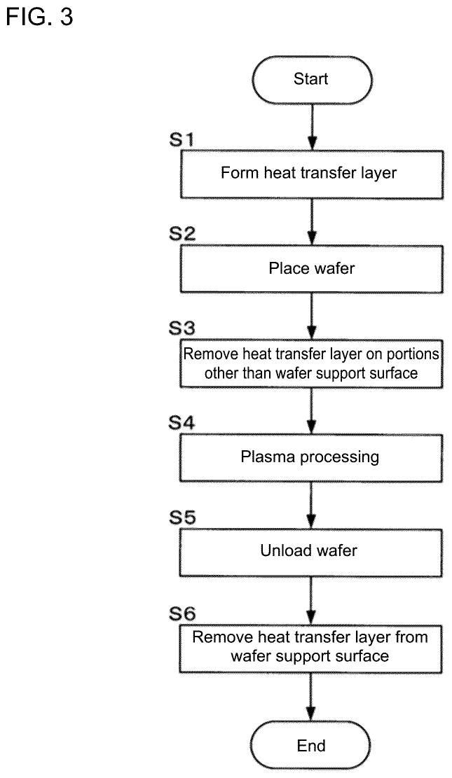

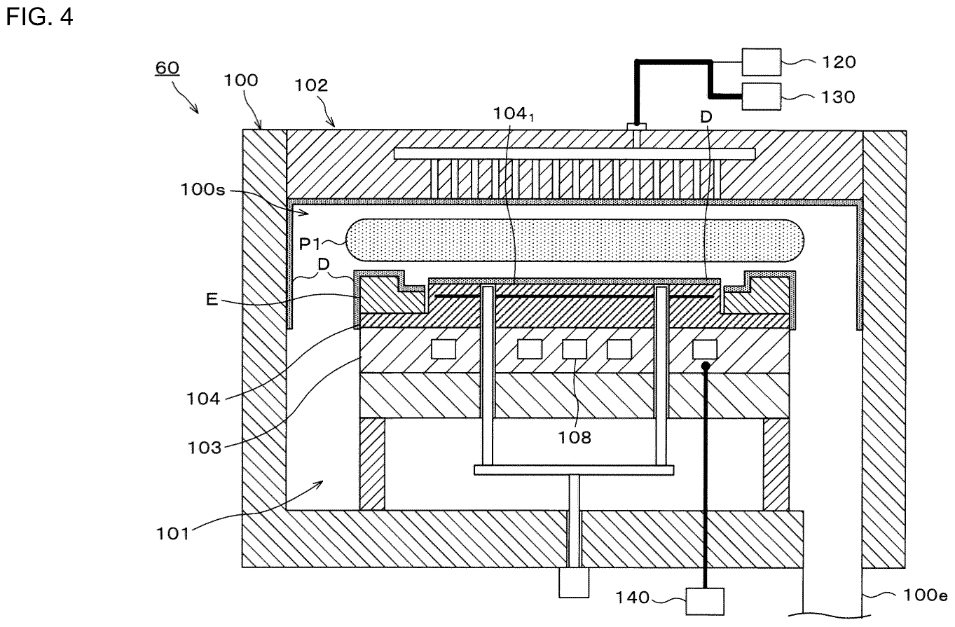

Example wafer processing performed in the processing module 60 will now be described with reference to FIGS. 3 to 8. FIG. 3 is a flowchart of example wafer processing. FIGS. 4 to 8 are each a diagram of the processing module 60 in a processing state during the wafer processing. The processing described below is performed under the control of the controller 80.

As shown in, for example, FIG. 3, a heat transfer layer D is formed on the wafer support surface 104₁ of the wafer support 101 (step S1).

More specifically, as shown in FIG. 4, a gas including a raw gas for the heat transfer layer D being liquid is first supplied from the gas supply unit 130 through the upper electrode 102 into the plasma processing chamber 100, which is decompressed to a predetermined degree of vacuum by the exhaust system 150.

In the present embodiment, the liquid in the heat transfer layer D has a low vapor pressure and a low melting point to maintain a liquid state under a low pressure and a low temperature. In the present embodiment, the wafer W is placed onto the wafer support surface 104₁ with the heat transfer layer D in between (described later). The liquid in the heat transfer layer D has high surface tension to avoid the liquid in the heat transfer layer D extending over the surface, or more specifically, over the upper surface of the wafer W when the wafer W is placed. The liquid in the heat transfer layer D may be ionic liquid. The liquid herein includes a sol or a gel with a liquid as a dispersant.

The raw gas for the heat transfer layer D includes, for example, at least one of boron (B) or carbon (C), which is a constituent atom of the heat transfer layer D, and at least one of hydrogen (H), nitrogen (N), or oxygen(O), which is a gas component. The raw gas for the heat transfer layer D may include components that do not interfere with plasma processing.

As described above, the gas including the raw gas is supplied, and RF power HF for plasma generation is provided from the RF power supply unit 140 to the lower electrode 103. This excites the raw gas and generates plasma P1. The generated plasma P1 then causes the heat transfer layer D being liquid to form on, for example, the wafer support surface 104₁. After the formation of the heat transfer layer D, the supply of the RF power HF from the RF power supply unit 140 and the supply of the gas including the raw gas from the gas supply unit 130 are stopped.

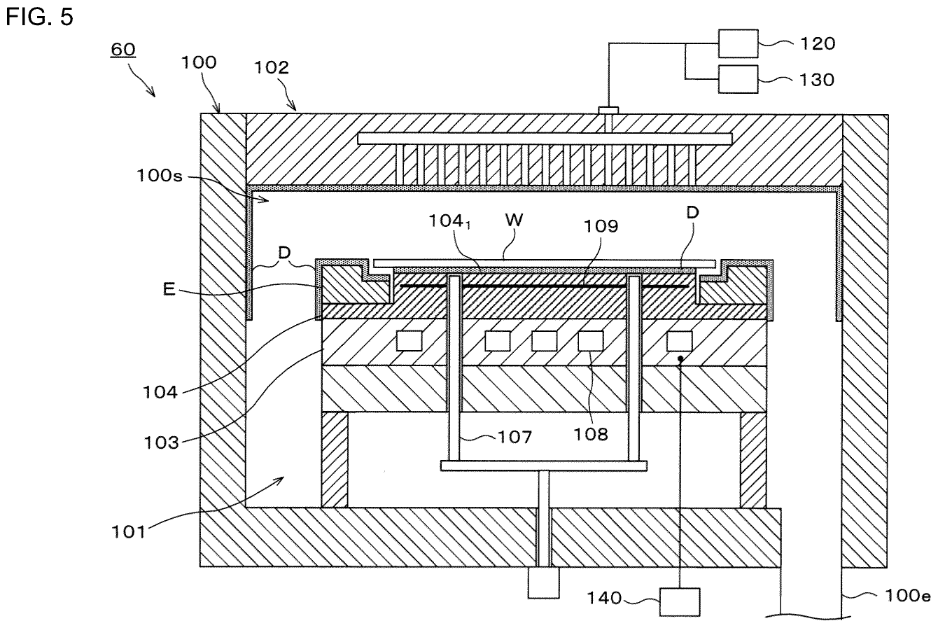

As shown in FIG. 5, the wafer W is then placed onto the wafer support surface 104₁ of the wafer support 101 (step S2).

More specifically, the wafer W is loaded into the plasma processing chamber 100 by the transferer 70, and is placed onto the wafer support surface 104₁ of the ESC 104 with the heat transfer layer D being liquid in between using the lifters 107 that can ascend or descend. The internal space of the plasma processing chamber 100 is then decompressed to a predetermined degree of vacuum by the exhaust system 150.

The heat transfer layer D formed on portions in the plasma processing chamber 100 other than the wafer support surface 104₁ is then removed (step S3).

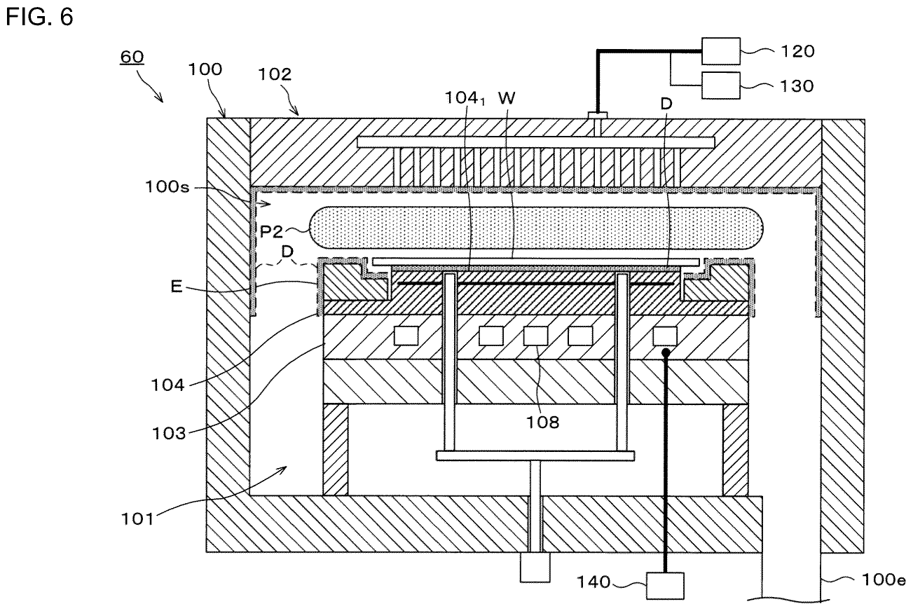

More specifically, as shown in FIG. 6, a removal gas for removing the heat transfer layer D is supplied from the gas supply unit 120 through the upper electrode 102 into the plasma processing space 100s, and RF power HF for plasma generation is provided from the RF power supply unit 140 to the lower electrode 103. This excites the removal gas and generates plasma P2. The generated plasma P2 then removes the heat transfer layer D formed on the portions other than the wafer support surface 104₁ (e.g., the upper surface and the outer peripheral surface of the edge ring E and the inner wall surface of the plasma processing chamber 100 such as the lower surface of the upper electrode 102). The heat transfer layer D formed on the wafer support surface 104₁ is covered with the wafer W and is not exposed to the plasma P2, remaining without being removed. After the removal of the heat transfer layer D, the supply of the RF power HF from the RF power supply unit 140 and the supply of the removal gas from the gas supply unit 120 are stopped.

Plasma processing including etching and film deposition is then performed on the wafer W on the wafer support surface 104₁, on which the heat transfer layer D is formed (step S4).

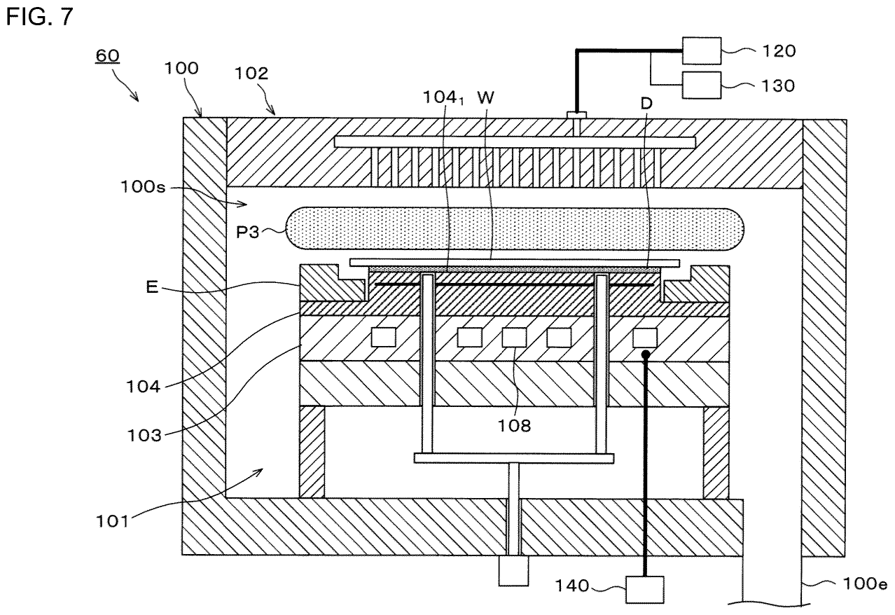

More specifically, as shown in FIG. 7, a process gas is supplied from the gas supply unit 120 through the upper electrode 102 into the plasma processing space 100s, and RF power HF for plasma generation is provided from the RF power supply unit 140 to the lower electrode 103. This excites the process gas and generates plasma P3. In this state, RF power LF for drawing ions may be provided from the RF power supply unit 140. The generated plasma P3 then causes plasma processing on the wafer W.

During plasma processing, the wafer support surface 104₁ is adjusted to a predetermined temperature with the temperature adjusting fluid flowing through the channel 108 to adjust the temperature of the wafer W. During plasma processing, the wafer W is on the wafer support surface 104₁ with the heat transfer layer D being liquid in between. The heat transfer layer D is formed from deformable liquid, allowing the lower surface, or the back surface, of the wafer W to be in close contact with the heat transfer layer D. The heat transfer layer D being liquid has higher thermal conductivity than a heat transfer gas, such as He. With the heat transfer layer D being liquid, the temperature of the wafer W can be adjusted more efficiently with the wafer support surface 104₁ than when a heat transfer gas, such as He, is supplied to between the wafer support surface 104₁ and the back surface of the wafer W. More specifically, when a large amount of heat is input from the plasma P3 to the wafer W during plasma processing, the wafer W can be maintained at a constant temperature by adjusting the temperature of the wafer support surface 104₁. When the set temperature for the wafer W is changed during plasma processing, the temperature of the wafer W can be immediately adjusted to the changed set temperature by adjusting the temperature of the wafer support surface 104₁.

During plasma processing, the wafer W may be held, or fastened, to the wafer support 101 (more specifically, the wafer support surface 104₁) to place the heat transfer layer D and the lower surface of the wafer W into closer contact. For example, the wafer W may be electrostatically clamped onto the wafer support surface 104₁ with an electrostatic force from the ESC 104. More specifically, a DC voltage may be applied to the electrode 109 in the ESC 104 to cause the ESC 104 to electrostatically clamp the wafer W with an electrostatic force. The temperature of the wafer W held as described above can be adjusted more efficiently.

The wafer W may be held on the wafer support 101 with, for example, an electrostatic force during the removal process of the heat transfer layer D in step S3.

When the wafer W is held on the wafer support 101 with an electrostatic force, the degree of contact of the wafer W with the wafer support 101 may be controlled using the electrostatic force to control heat removal from the wafer W through the wafer support 101.

Similarly, the edge ring E may be held, or fastened, to the wafer support 101 during plasma processing. For example, a DC voltage may be applied to the electrodes (not shown) for electrostatically clamping the edge ring in the ESC 104. This causes the ESC 104 to electrostatically clamp the edge ring E with an electrostatic force.

During plasma processing, a heat transfer gas may be supplied to the back surface of the edge ring E through gas supply holes (not shown) in the peripheral upper surface 104₂ of the ESC 104.

The removal of the heat transfer layer D in step S3 and the plasma processing in step S4 may be performed simultaneously. For the plasma processing being film deposition as well, the removal of the heat transfer layer D in step S3 and the plasma processing in step S4 can be performed simultaneously when the types of gas introduced into the plasma processing space 100s are selected appropriately.

To end the plasma processing, the supply of the RF power HF from the RF power supply unit 140 and the supply of the process gas from the gas supply unit 130 are stopped. When RF power LF is provided during plasma processing, the supply of the RF power LF is also stopped. When the wafer W is electrostatically clamped by the ESC 104 during plasma processing, the electrostatic clamping is also stopped. When the edge ring E is electrostatically clamped by the ESC 104 and the heat transfer gas is supplied to the back surface of the edge ring E during plasma processing, at least one of these operations may also be stopped.

After plasma processing, the wafer W is separated from the wafer support surface 104₁ and unloaded (step S5).

More specifically, the wafer W is raised by the lifters 107 to separate the wafer W from the heat transfer layer D received on the wafer support surface 104₁. The wafer W is then transferred from the lifters 107 to the transferer 70, and is unloaded from the plasma processing chamber 100 by the transferer 70.

The heat transfer layer D is then removed from the wafer support surface 104₁ (step S6).

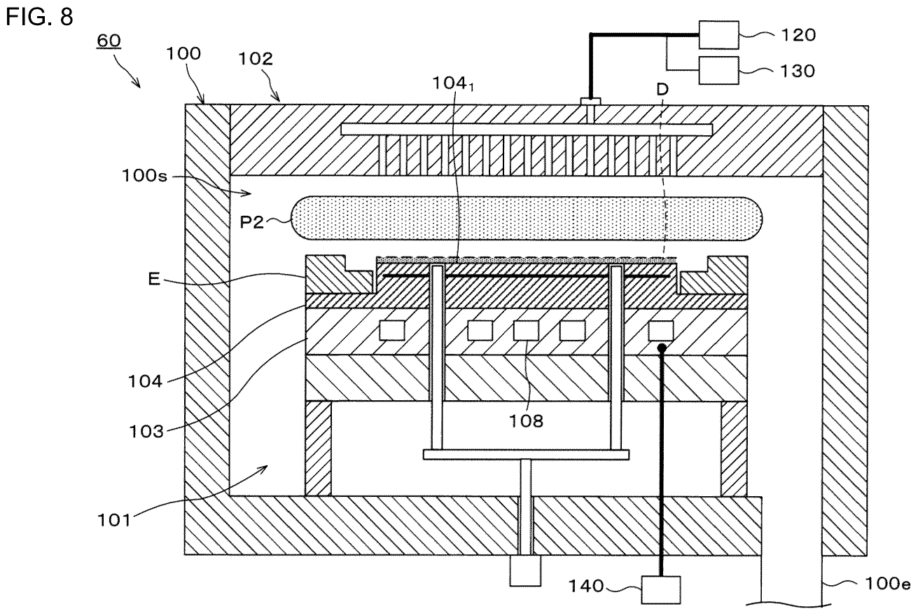

More specifically, as shown in FIG. 8, the removal gas for removing the heat transfer layer D is supplied from the gas supply unit 120 through the upper electrode 102 into the plasma processing space 100s, and RF power HF for plasma generation is provided from the RF power supply unit 140 to the lower electrode 103. This excites the removal gas and generates the plasma P2. The generated plasma P2 then removes the heat transfer layer D from the wafer support surface 104₁. After the removal of the heat transfer layer D, the supply of the RF power HF from the RF power supply unit 140 and the supply of the removal gas from the gas supply unit 120 are stopped. This completes the wafer processing.

The heat transfer layer D may not be removed from the wafer support surface 104₁ in step S6 for each wafer W. In other words, the heat transfer layer D on the wafer support surface 104₁ may be used for multiple wafers W.

When the heat transfer layer D is removed from the wafer support surface 104₁, the edge ring E may be held, or fastened, to the wafer support 101. For example, a DC voltage may be applied to the electrodes (not shown) for electrostatically clamping the edge ring in the ESC 104. This causes the ESC 104 to electrostatically clamp the edge ring E with an electrostatic force.

When the heat transfer layer D is removed from the wafer support surface 104₁, a heat transfer gas may be supplied to the back surface of the edge ring E through gas supply holes (not shown) in the peripheral upper surface 104₂ of the ESC 104.

### Other Examples of Heat Transfer Layer D

In the above example, the heat transfer layer D is a liquid layer. However, the heat transfer layer D may be a solid layer when it is deformable. Being deformable refers to, for example, the wafer W being deformable with its weight. When the wafer W is electrostatically clamped by the ESC 104, being deformable may refer to the wafer W being deformable when an electrostatic clamping force is applied to the wafer W.

The heat transfer layer D may be a combination of a liquid layer and a solid layer when it is deformable.

In other words, the heat transfer layer D is a deformable layer including at least one of a liquid layer or a solid layer. The heat transfer layer D may include a deformable uppermost layer, which is in contact with the back surface of the wafer W, being a liquid layer, a solid layer, or a combination of these, and a solid layer that is not deformable.

The solid included in the heat transfer layer D may have, for example, an elastic modulus allowing the heat transfer layer D to be deformable with the weight of the wafer W, or may have an elastic modulus allowing the heat transfer layer D to be deformable with an electrostatic clamping force applied to the wafer W. More specifically, the solid included in the heat transfer layer D is, for example, an elastic polymer, or in other words, an elastomer.

### Advantageous Effects and Others

In the present embodiment described above, the deformable heat transfer layer D including at least one of a liquid layer or a solid layer is located on the wafer support surface 104₁ of the wafer support 101, and plasma processing is performed on the wafer W on the wafer support surface 104₁ on which the heat transfer layer D is formed. The above heat transfer layer D includes at least one of a liquid layer or a solid layer, and thus has higher thermal conductivity than a heat transfer layer formed from a heat transfer gas. The above heat transfer layer D is deformable and can thus be closely in contact with the lower surface of the wafer W. In the present embodiment, heat can thus be efficiently exchanged between the wafer W and the wafer support surface 104₁ through the heat transfer layer D. The temperature of the wafer W is efficiently adjustable through the wafer support surface 104₁ during plasma processing. More specifically, during plasma processing, the wafer support surface 104₁ can efficiently absorb heat from the wafer W through the heat transfer layer D, and the wafer support surface 104₁ can efficiently heat the wafer W through the heat transfer layer D.

In the present embodiment, heat can be efficiently exchanged between the wafer W and the wafer support surface 104₁ through the heat transfer layer D as described above. This eliminates the temperature difference between the wafer W and the wafer support surface 104₁ immediately after the wafer W is placed onto the wafer support surface 104₁.

In the present embodiment, as described above, the wafer W may be electrostatically clamped onto the wafer support surface 104₁ with an electrostatic force from the ESC 104 during plasma processing. This allows the heat transfer layer D and the lower surface of the wafer W to be in closer contact with each other, further improving the efficiency of heat removal from the wafer W or the efficiency of heating the wafer W through the wafer support surface 104₁ and the heat transfer layer D. As described above, the ESC 104 electrostatically clamping the wafer W allows the heat transfer layer D to be in close contact with the lower surface of the wafer W when the wafer W is warped. Thus, with the wafer W being warped, the heat may be efficiently removed from the wafer W or the wafer W may be heated efficiently.

Modifications of Forming Heat Transfer Layer D from Raw Gas

In the above example, the heat transfer layer D is formed from a raw gas using plasma. However, the heat transfer layer D may be formed in any manner.

For example, a portion to be the heat transfer layer D may be cooled. The cooled portion is then used to at least liquefy or solidify the raw gas (or in other words, condensation or deposition) to form the heat transfer layer D. More specifically, a raw gas that liquefies or solidifies in a vacuum below a predetermined temperature may be used to form the heat transfer layer D on the wafer support surface 104₁ when the wafer support surface 104₁ is cooled below the predetermined temperature. More specifically, a raw gas that liquefies or solidifies at a temperature lower than the set temperature of the plasma processing chamber 100 may be used, and the temperature of the wafer support surface 104₁ may be cooled below the temperature at which the raw gas can at least liquefy or solidify. This allows the heat transfer layer D to be selectively formed on the wafer support surface 104₁ alone without being formed on the edge ring E or other portions. The step of removing the heat transfer layer D formed on the portions other than the wafer support surface 104₁ in step S3 described above can be eliminated, thus improving the throughput.

After supplying a raw gas into the plasma processing space 100s in the plasma processing chamber 100, the pressure in the plasma processing space 100s may be increased to cause the raw gas to at least liquefy or solidify, thus forming the heat transfer layer D.

The raw gas may further be irradiated with light in the plasma processing space 100s to cause the raw gas to at least liquefy or solidify, thus forming the heat transfer layer D. In this case, the light source is located, for example, outside the plasma processing chamber 100 and irradiates the raw gas with light in the plasma processing space 100s through an optical window (not shown) in the plasma processing chamber 100.

When the heat transfer layer D is formed from a raw gas in the plasma processing space 100s using plasma or light and the wafer support surface 104₁ is formed from a material different from the material of the edge ring E or the material of the inner wall surface of the plasma processing chamber 100, the raw gas described below may be used. The raw gas may be a substance that is generated from the raw gas using plasma or light and form the heat transfer layer D. The substance may be selectively adsorbed on the wafer support surface 104₁ alone, without being adsorbed on the edge ring E or the inner wall surface of the plasma processing chamber 100. This also allows the heat transfer layer D to be selectively formed on the wafer support surface 104₁ alone, thus eliminating the step of removing the heat transfer layer D formed on the portions other than the wafer support surface 104₁ in step S3 described above.

After a solid layer is formed on the wafer support surface 104₁ from the raw gas using plasma or light, the wafer W placed on the wafer support surface 104₁ is electrostatically clamped by the ESC 104. The solid layer may be pressurized by the wafer W to liquefy, forming the heat transfer layer D being liquid.

### Example State of Heat Transfer Layer D on Wafer Support Surface 104₁

The heat transfer layer D is formed on the entire wafer support surface 104₁, including, for example, the central area and the peripheral area of the wafer support surface 104₁. In some embodiments, the heat transfer layer D may be formed on a part of the wafer support surface 104₁. For example, when heat is to be removed from or to be added to the center portion of the wafer W, the heat transfer layer D may be formed on the central area of the wafer support surface 104₁ facing the center portion of the wafer W. For example, when heat is to be removed from or to be added to the periphery of the wafer W, the heat transfer layer D may be formed on the peripheral area of the wafer support surface 104₁ facing the periphery of the wafer W.

An example method for forming the heat transfer layer D on a part of the wafer support surface 104₁ will be described below. A raw gas that liquefies or solidifies in a vacuum below a predetermined temperature is used. The wafer support surface 104₁ has a target portion to be cooled below the predetermined temperature to form the heat transfer layer D on the target portion of the wafer support surface 104₁.

The heat transfer layer D has a uniform thickness across the entire wafer support surface 104₁ including, for example, the central area and the peripheral area of the wafer support surface 104₁. In some embodiments, the heat transfer layer D may have different thicknesses within the plane of the wafer support surface 104₁. For example, when heat is to be removed from or to be added to the center portion of the wafer W, the heat transfer layer D may be thinner on the central area of the wafer support surface 104₁ facing the center portion of the wafer W than on the peripheral area. For example, when heat is to be removed from or to be added to the periphery of the wafer W, the heat transfer layer D may be thinner on the peripheral area of the wafer support surface 104₁ facing the periphery of the wafer W than on the central area. Thus, the heat transfer layer D being partially thinner on, for example, the central area of the wafer support surface 104₁ allows the heat exchange efficiency between the wafer support surface 104₁ and the wafer W to vary within the plane. The heat exchange efficiency can thus be partially increased in, for example, the central area of the wafer support surface 104₁.

An example method for varying the thickness of the heat transfer layer D within the plane of the wafer support surface 104₁ will be described below. The wafer support surface 104₁ may have a different temperature in an area from the other areas during formation of the heat transfer layer D. The heat transfer layer D can thus have different thicknesses within the plane of the wafer support surface 104₁.

### Modifications of Raw Gas Supply

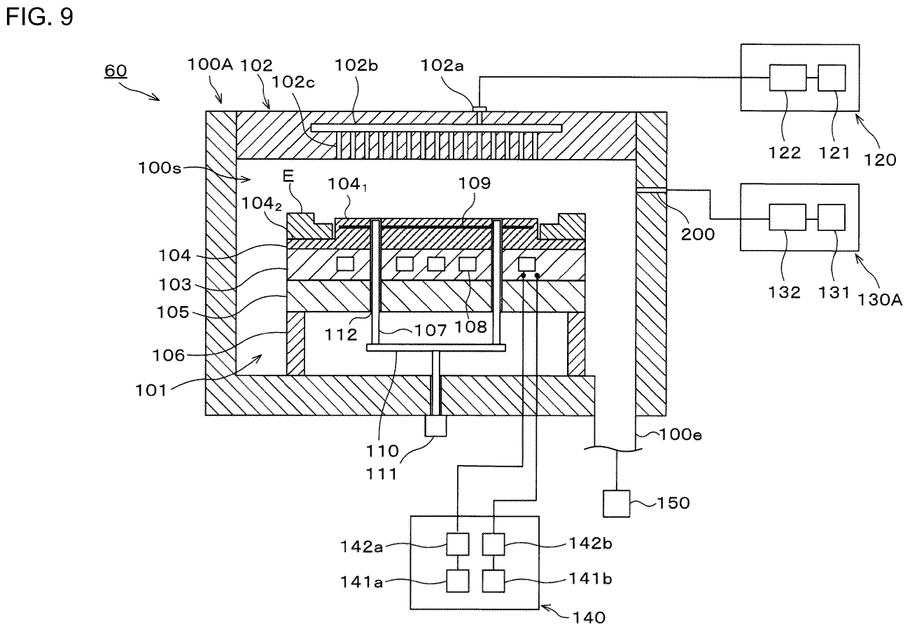

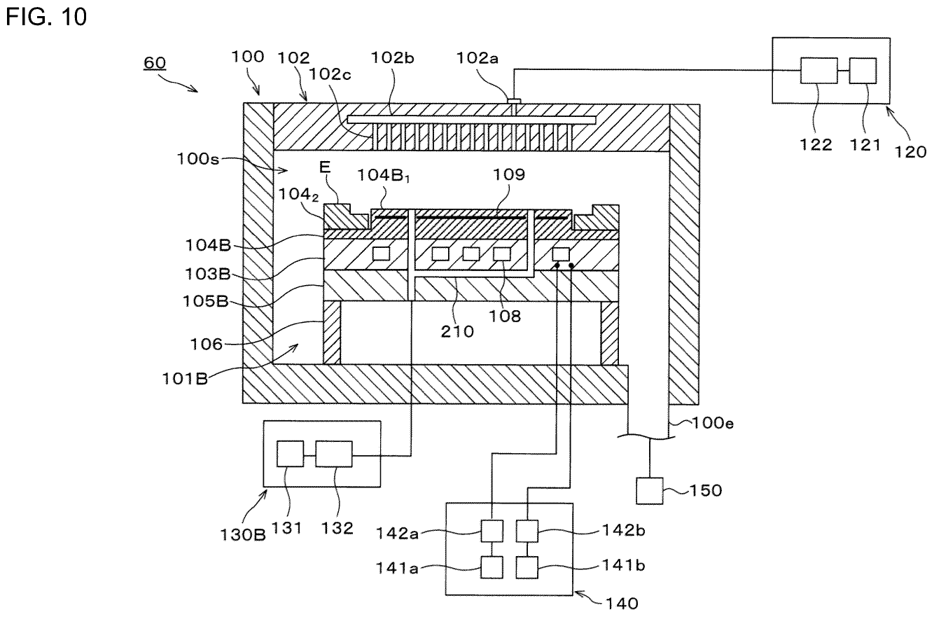

FIGS. 9 to 12 are each a diagram describing a modification of raw gas supply. FIG. 10 shows a wafer support in a cross section focusing on its components different from the components shown in FIG. 4 and other figures.

In the above example, the raw gas is supplied into the plasma processing space 100s through the upper electrode 102, which is also used to supply a process gas. In some embodiments, the raw gas may be supplied through a wall defining the plasma processing space 100s, rather than through the upper electrode 102 in the plasma processing chamber 100. As shown in FIG. 9, for example, a gas port 200 allowing passage of fluid to the plasma processing space 100s and fluidly connected to a gas supply unit 130A may be located in a side wall of a plasma processing chamber 100A. The gas port 200 allows supply of the raw gas from the gas supply unit 130A to the plasma processing space 100s through the side wall (more specifically, the gas port 200).

A gas outlet other than the gas port 102c used for supplying the process gas may be located in the upper electrode 102, and the raw gas may be supplied from the gas supply unit to the plasma processing space 100s through the other gas outlet.

The raw gas may be supplied into the plasma processing space 100s through the wafer support.

As shown in, for example, FIG. 10, a channel 210 having its ends being open in a wafer support surface 104B₁ and another end fluidly connected to a gas supply unit 130B may be located in a wafer support 101B. The channel 210 allows supply of the raw gas from the gas supply unit 130B to the plasma processing space 100s. The channel 210 extends through, for example, an ESC 104B, a lower electrode 103B, and an insulator 105B.

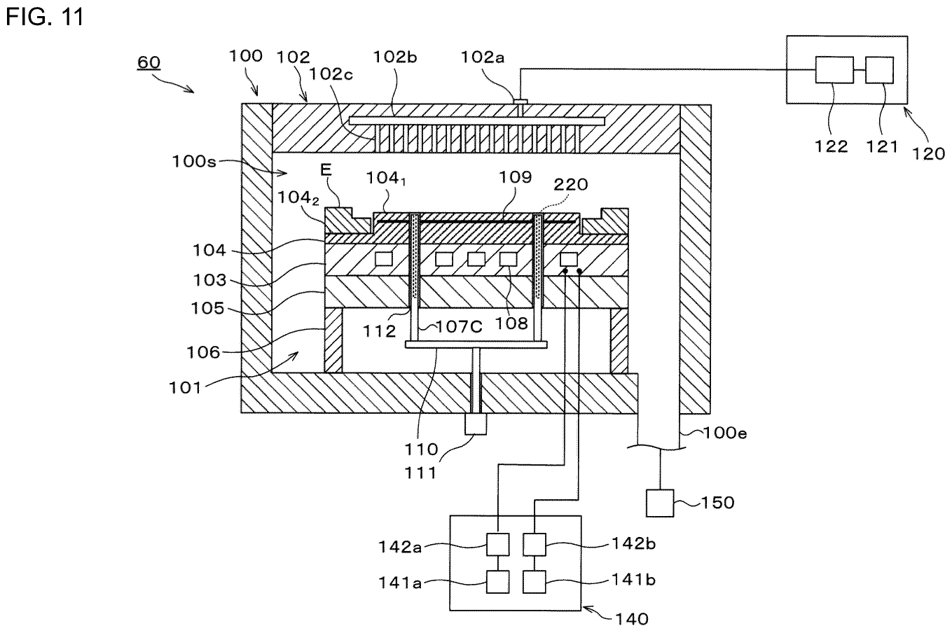

In some embodiments, as shown in FIG. 11, for example, gas outlets 220 allowing passage of fluid to the plasma processing space 100s and fluidly connected to a gas supply unit (not shown) may be located in lifters 107C. The gas outlets 220 allow supply of the raw gas from the gas supply unit (not shown) to the plasma processing space 100s.

The raw gas may also be supplied into the plasma processing space 100s through a transferer that transfers the wafer W to the processing module 60.

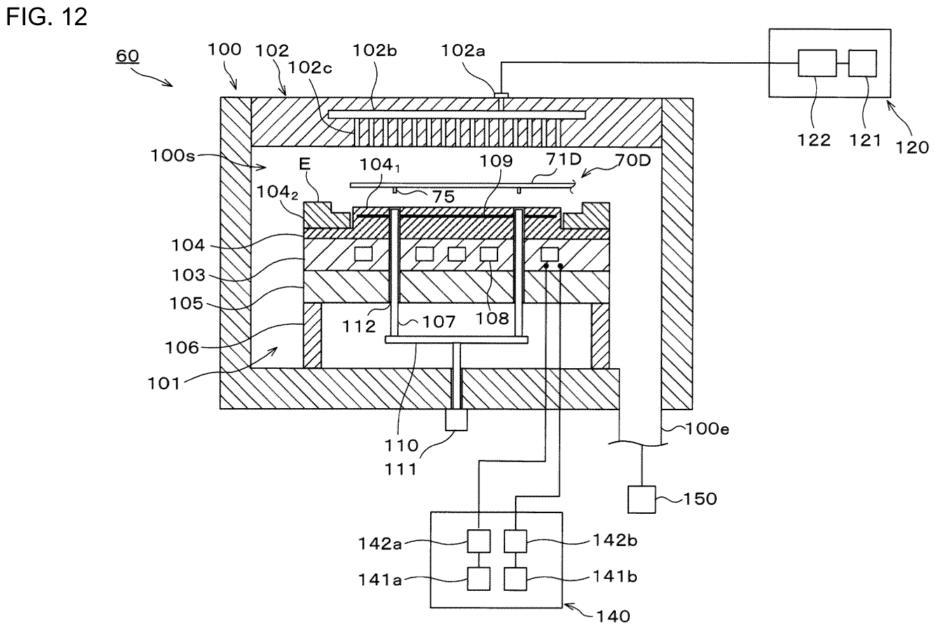

As shown in, for example, FIG. 12, nozzles 75 fluidly connected to a gas supply unit (not shown) may be located in a transfer arm 71D in the transferer 70D. The nozzles 75 allow, with the transfer arm 71D placed into the plasma processing chamber 100, supply of the raw gas from the gas supply unit (not shown) to the plasma processing space 100s.

Multiple types of raw gases may be supplied into the plasma processing space 100s through different portions of the plasma processing apparatus. This allows multiple types of reaction gases to react with one another to form the heat transfer layer D. For example, one raw gas may be supplied through gas ports 102c and another raw gas may be supplied through the gas port 200 (refer to FIG. 9). The raw gas and the other raw gas may react in the plasma processing space 100s to form the heat transfer layer D.

### Modifications of Removal of Heat Transfer Layer D Formed on Portion Other Than Wafer Support Surface

In the above example, plasma is used to remove the heat transfer layer D formed on portions other than the wafer support surface. However, the heat transfer layer D may be removed in any manner.

For example, a portion other than the wafer support surface on which the heat transfer layer D is formed (e.g., an inner wall surface of the plasma processing chamber 100) may be heated to vaporize and selectively remove the heat transfer layer D formed on the portion.

In some embodiments, the heat transfer layer D formed on a portion other than the wafer support surface may be irradiated with light to vaporize and selectively remove the heat transfer layer D. In this case, the light source is, for example, located outside the plasma processing chamber 100 and applies light onto the heat transfer layer D formed on the portion in the plasma processing chamber 100 other than the wafer support surface through the optical window in the plasma processing chamber 100.

The plasma processing chamber 100 may further be exhausted with the wafer W placed on the wafer support surface to vaporize and remove the heat transfer layer D formed on the portion other than the wafer support surface. More specifically, the plasma processing chamber 100 may be exhausted to a low pressure (e.g., below a vapor pressure) with the wafer W placed on the wafer support surface, exposing the heat transfer layer D formed on the portion other than the wafer support surface to a decompressed atmosphere to vaporize and remove the heat transfer layer D. In this case, the wafer W may be fastened to the wafer support surface to reduce vaporization of the heat transfer layer D on the wafer support surface. For example, a DC voltage may be applied to the electrode 109 in the ESC 104 to electrostatically clamp the wafer W with the ESC 104 with an electrostatic force.

To remove the heat transfer layer D formed on the portion other than the wafer support surface with heat or light, the wafer W may not be placed on the wafer support surface. In this case, the wafer support surface may be cooled. This reduces vaporization of the heat transfer layer D on the wafer support surface.

### Modifications of Removal of Heat Transfer Layer D Formed on Wafer Support Surface

In the above example, plasma is used to remove the heat transfer layer D formed on the wafer support surface. However, the heat transfer layer D may be removed in any manner.

For example, the temperature of the wafer support surface may be increased to vaporize and remove the heat transfer layer D formed on the wafer support surface.

In some embodiments, the heat transfer layer D formed on the wafer support surface may be irradiated with light to be removed. In this case, the light source is, for example, located outside the plasma processing chamber 100 and applies light onto the heat transfer layer D formed on the wafer support surface through the optical window in the plasma processing chamber 100.

The plasma processing chamber 100 may further be exhausted to vaporize and remove the heat transfer layer D formed on the wafer support surface. More specifically, the plasma processing chamber 100 may be exhausted to a low pressure (e.g., below a vapor pressure), exposing the heat transfer layer D formed on the wafer support surface to a decompressed atmosphere to vaporize and remove the heat transfer layer D.

For the heat transfer layer D including, for example, solid alone and less likely to be separate from the wafer W, the heat transfer layer D may be removed as described below. The heat transfer layer D is fixed to the lower surface of the wafer W with, for example, an adhesive force from the heat transfer layer D. After plasma processing, the wafer W with the heat transfer layer D may be raised to separate the wafer W from the wafer support surface and unloaded from the plasma processing chamber 100. This can also remove the heat transfer layer D formed on the wafer support surface. In this case, the heat transfer layer D received on the lower surface of the wafer W may be removed in the transfer module 50, the loadlock module 20 or 21, or the loader module 30. For example, heat or light is used to remove the heat transfer layer D. The wafer W with the heat transfer layer D fixed to its lower surface may be stored in the FOUP 31.

### Plasma Processing Chamber 100 in Another Example State in Forming Heat Transfer Layer D

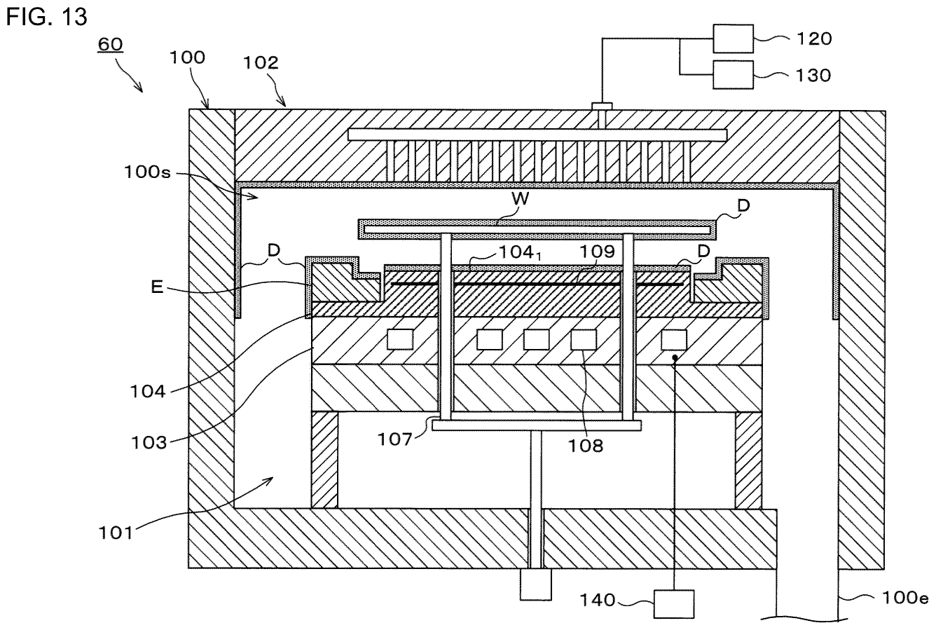

FIG. 13 is diagram of the plasma processing chamber 100 in another example state in forming the heat transfer layer D.

In the above example, the wafer W is not located in the plasma processing chamber 100 during formation of the heat transfer layer D. In some embodiments, the wafer W may be located in the plasma processing chamber 100 during the formation.

More specifically, as shown in FIG. 13, the wafer W may be located in the plasma processing chamber 100 and separate from the wafer support surface 104₁ during formation of the heat transfer layer D. More specifically, with the wafer W supported by the lifters 107 to be separate from the wafer support surface 104₁, a raw gas may be supplied into the plasma processing chamber 100 and liquefy or solidify, thus forming the heat transfer layer D.

When the heat transfer layer D is formed as the example described above, the heat transfer layer D may be formed on the back or lower surface, the front or upper surface, and the side end surfaces of the wafer W. In this case, the heat transfer layer D formed on the lower surface of the wafer W is negligible, but the heat transfer layers D formed on other surfaces, or in particular, on the upper surface of wafer W, may interfere with plasma processing.

The heat transfer layer D formed on the upper surface of wafer W can be selectively removed as described below before plasma processing, without removing the heat transfer layer D formed on the wafer support surface. More specifically, the internal space of the plasma processing chamber 100 may be decompressed with the wafer W placed on the wafer support surface on which the heat transfer layer D is formed. This allows the heat transfer layer D formed on the upper surface of the wafer W to be selectively removed before plasma processing. The heat transfer layer D formed on the upper surface of the wafer W may also be selectively removed using plasma, heat, or light with the wafer W placed on the wafer support surface on which the heat transfer layer D is formed.

When the heat transfer layer D formed on the upper surface of the wafer W is removed, the heat transfer layers formed on other unintended portions, or in other words, on the upper surface of the wafer W and portions other than the wafer support surface may also be removed.

When the internal space of the plasma processing chamber 100 is decompressed with the wafer W placed on the wafer support surface on which the heat transfer layer D is formed to selectively remove the heat transfer layer D formed on the upper surface of the wafer W, the wafer W may be fastened to the wafer support surface to reduce vaporization of the heat transfer layer D formed on the wafer support surface. For example, a DC voltage may be applied to the electrode 109 in the ESC 104 to electrostatically clamp the wafer W with the ESC 104 with an electrostatic force.

When the heat transfer layer D is formed with the wafer W supported by the lifters 107 to be separate from the wafer support surface 104₁, as described in this example, a restrictor may restrict the formation of the heat transfer layer D on the lifters 107. For example, when the raw gas is cooled to liquefy or solidify to form the heat transfer layer D, a heater such as a heating resistor may be located in each lifter 107 as the restrictor, and the lifter 107 may be heated to a high temperature.

Other Modifications of Formation of Heat Transfer Layer D from Raw Gas

In the above example, the raw gas liquefies or solidifies to form the heat transfer layer D directly on the wafer support surface. In some embodiments, the heat transfer layer D may be formed on the wafer support surface as described below.

The raw gas supplied into the plasma processing chamber 100 may at least liquefy or solidify to form the heat transfer layer D at least on the lower surface of the wafer W in the plasma processing chamber 100, without forming the heat transfer layer D on the wafer support surface. More specifically, the controller 80 may control the raw gas supplied from the gas supply unit 130 into the plasma processing chamber 100 to at least liquefy or solidify. This allows the heat transfer layer D to be formed at least on the lower surface of the wafer W supported by the lifters 107 to be separate from the wafer support surface 104₁, without allowing the heat transfer layer D to be formed on the wafer support surface. The wafer W receiving the heat transfer layer D on its lower surface may then be placed onto the wafer support surface, thus forming the heat transfer layer D on the wafer support surface. More specifically, the controller 80 may control the lifters 107 to descend to place the wafer W receiving the heat transfer layer on its lower surface onto the wafer support surface, thus forming the heat transfer layer D on the wafer support surface.

To selectively form the heat transfer layer D on the wafer W as described above, for example, the wafer W may be pre-cooled before being loaded into the plasma processing chamber 100 (more specifically, before being supported with the lifters 107). When the wafer W is pre-cooled in this manner, each lifter 107 may have its distal end, or an upper end, formed from an insulating material. This reduces the likelihood of the lifter 107 being cooled by the heat transfer with the wafer W, thus reducing formation of the heat transfer layer D on the lifter 107

The pre-cooling of the wafer W is performed in, for example, the transfer module 50, the loadlock module 20 or 21, or the loader module 30.

In this example, the controller 80, the lift assembly including the lifters 107 for the wafer W, and the gas supply unit 130 may serve as at least a part of a heat transfer layer formation unit to form the heat transfer layer D on the wafer support surface.

### Second Embodiment

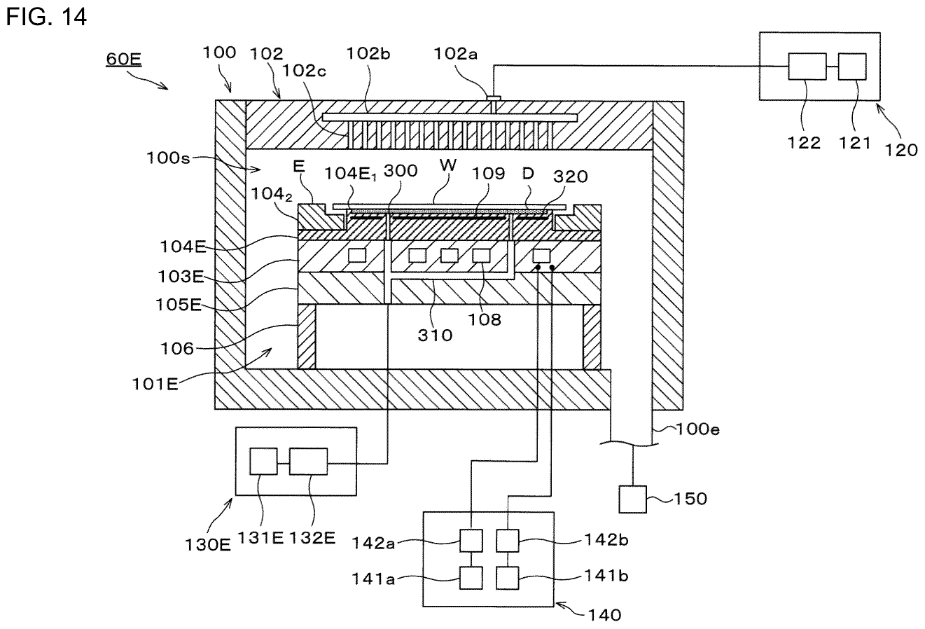

FIG. 14 is a schematic longitudinal cross-sectional view of a processing module as a plasma processing apparatus according to a second embodiment. FIG. 14 shows a wafer support in a cross section focusing on its components different from the components in FIG. 4 and other figures, and thus the lifters 107, the support 110, and the drive 111 are not shown in the figure. In other words, a processing module 60E in FIG. 14 includes the lifters 107, the support 110, and the drive 111, similarly to the processing module 60 in FIG. 2.

In the first embodiment, the heat transfer layer D is formed from a raw gas supplied into the plasma processing space 100s. In contrast, in the present embodiment, a heat transfer medium including at least one of a liquid medium or a solid medium with fluidity is supplied to a wafer support surface 104E₁ through a wafer support 101E to form a heat transfer layer D from the above heat transfer medium.

Thus, in the processing module 60E in FIG. 14, supply ports 300 for the heat transfer medium are located in the wafer support surface 104E₁ of an ESC 104E in the wafer support 101E. For example, multiple supply ports 300 are located in the wafer support surface 104E₁.

The wafer support surface 104E₁ may have grooves 320. The grooves 320 allow the heat transfer medium to flow and spread along the wafer support surface 104E₁.

A channel 310 is located in the wafer support 101E. The channel 310 has its ends connected to the respective supply ports 300 to allow fluid passage. The channel 310 has another end, opposite to these ends, that is fluidly connected to, for example, a gas supply unit 130E. The channel 310 has, for example, thinner ends adjacent to the wafer support surface 104E₁ (more specifically, for example, a portion inside the ESC 104E). The heat transfer medium in the channel 310 is supplied to the wafer support surface 104E₁ by capillary action through the supply ports 300. The channel 310 extends through, for example, the ESC 104E, a lower electrode 103E, and an insulator 105E.

The gas supply unit 130E may include one or more gas sources 131E and one or more flow controllers 132E. In one embodiment, the gas supply unit 130E supplies, for example, one or more gases for generating the heat transfer medium described above (hereafter, heat transfer medium generation gases) from the respective gas sources 131E to the wafer support 101E through the corresponding flow controllers 132E. Each flow controller 132E may include, for example, a mass flow controller or a pressure-based flow controller. The gas supply unit 130E may further include one or more flow rate modulators that supply one or more heat transfer medium generation gases at a modulated flow rate or in a pulsed manner.

The heat transfer medium generation gas supplied from the gas supply unit 130E is cooled in the channel 310 by, for example, the lower electrode 103E cooled by a temperature adjusting fluid, liquefies or solidifies, and then turns into a heat transfer medium including at least a liquid medium or a solid medium with fluidity. As described above, the heat transfer medium is supplied to the wafer support surface 104E₁ by, for example, capillary action, through the supply ports 300 to form the heat transfer layer D. The gas supply unit 130E may thus serve as at least a part of a heat transfer layer formation unit to form the heat transfer layer D on the wafer support surface 104E₁.

### Wafer Processing in Processing Module 60E

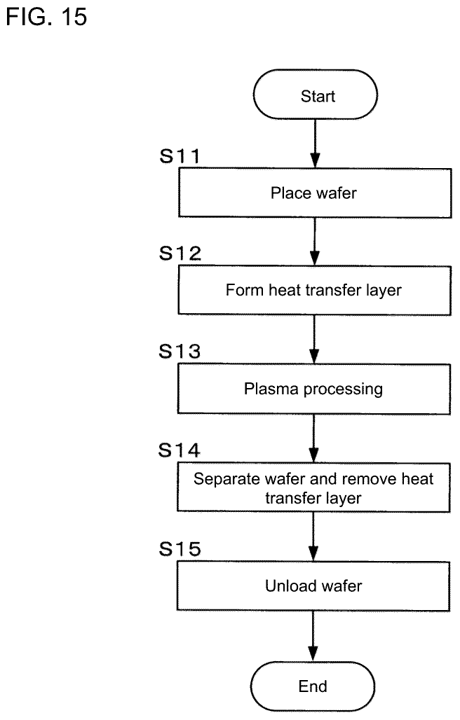

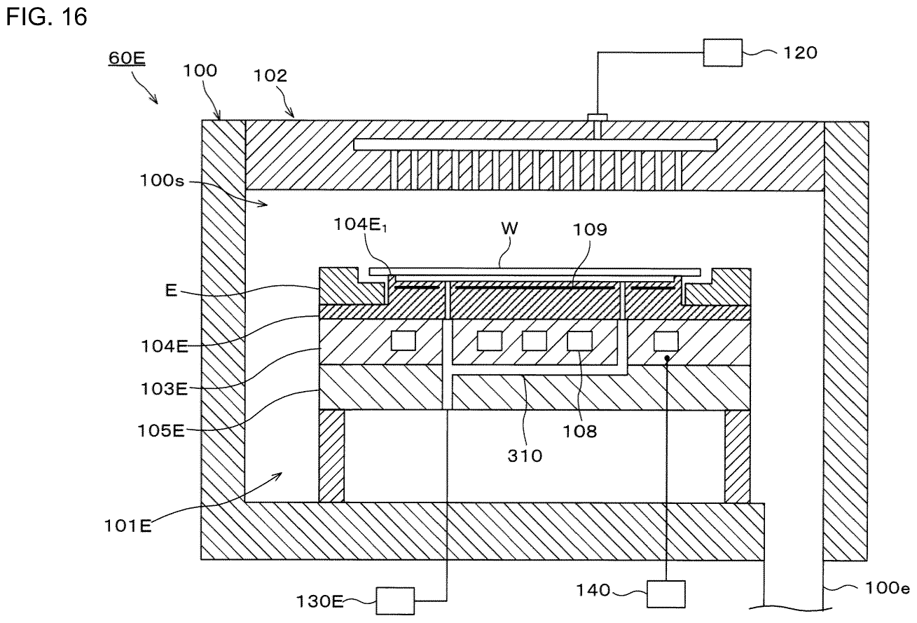

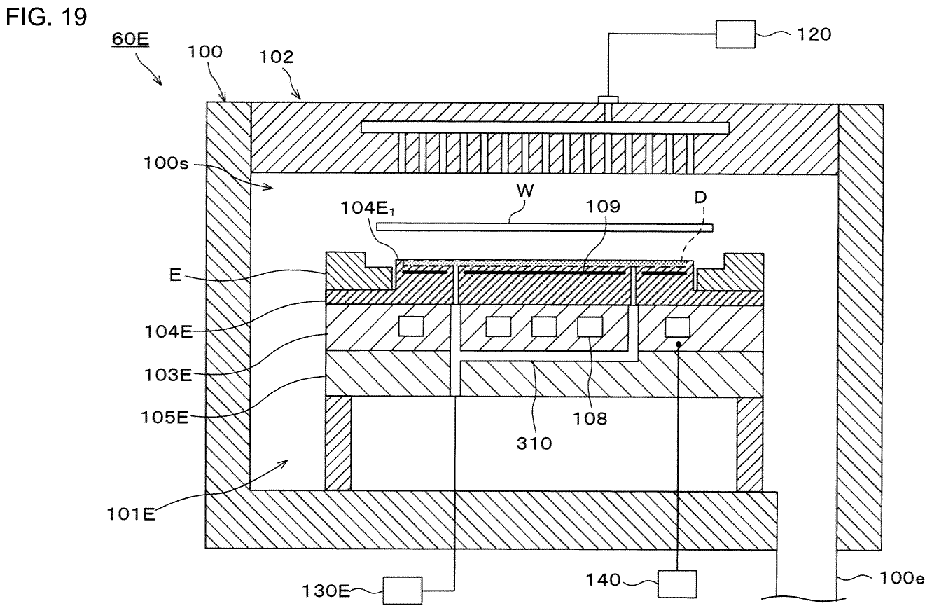

Example wafer processing performed in the processing module 60E will now be described with reference to FIGS. 15 to 19. FIG. 15 is a flowchart of example wafer processing. FIGS. 16 to 19 are each a diagram of the processing module 60E in a processing state during the wafer processing. The processing described below is performed under the control of the controller 80.

As shown in FIGS. 15 and 16, a wafer W is placed onto the wafer support surface 104E₁ of the wafer support 101E (step S11).

More specifically, the wafer W is loaded into the plasma processing chamber 100 by the transferer 70, and is placed onto the wafer support surface 104E₁ of the ESC 104E using the lifters 107 that can ascend or descend. The internal space of the plasma processing chamber 100 is then decompressed to a predetermined degree of vacuum (pressure p1) by the exhaust system 150.

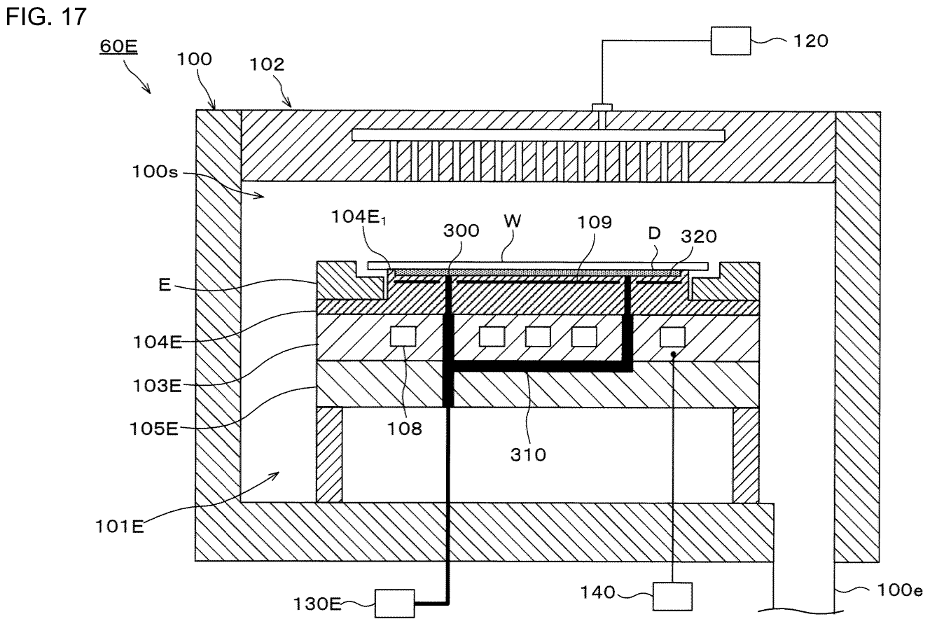

As shown in FIG. 17, a deformable heat transfer layer D including at least one of a liquid layer or a solid layer is then formed on the wafer support surface 104E₁ (step S12). More specifically, a heat transfer medium including at least one of a liquid medium or a solid medium with fluidity is supplied to between the wafer support surface 104E₁ and the back surface of the wafer W through the wafer support surface 104E₁ to form the heat transfer layer D.

More specifically, the wafer W is held on the wafer support 101E. For example, a DC voltage is applied to an electrode 109 in the ESC 104E to electrostatically clamp the wafer W with the ESC 104 with an electrostatic force. In this case, the temperature of the wafer support surface 104E₁ is adjusted to a temperature T1, and the temperature in the channel 310 is adjusted to the temperature T1 accordingly. The temperature T1 is set to a temperature at which the processing can be performed effectively. The temperature T1 may be, for example, equal to the temperature of the wafer support surface 104E₁ during the processing.

After the wafer W is held on the wafer support 101E, a heat transfer medium generation gas is supplied from the gas supply unit 130E to the channel 310 in the wafer support 101E at a temperature T2 (>T1) and a pressure p2 (>p1). The heat transfer medium generation gas supplied to the channel 310 is cooled to the temperature T1 in the channel 310, and turns into a heat transfer medium including at least one of a liquid medium or a solid medium with fluidity. The heat transfer medium is then supplied to the wafer support surface 104E₁ by, for example, capillary action, through the supply ports 300. The heat transfer medium supplied to the wafer support surface 104E₁ spreads along the wafer support surface 104E₁ by capillary action, which results from a clearance between the wafer support surface 104E₁ and the back surface of the wafer W. This forms the heat transfer layer D. The heat transfer layer D is formed from the heat transfer medium including at least one of a liquid medium or a solid medium with fluidity. The heat transfer layer D is thus a layer including at least one of a liquid medium or a solid medium with fluidity, as in the first embodiment, and is also deformable.

With a clearance between the wafer support surface 104E₁ and the back surface of the wafer W being too narrow, the heat transfer medium may not spread along the wafer support surface 104E₁ by capillary action, depending on the viscosity of the heat transfer medium. As described above, the grooves 320 on the wafer support surface 104E₁ widen the clearance between the wafer support surface 104E₁ and the back surface of the wafer W. This allows the heat transfer medium to spread appropriately along the wafer support surface 104E₁ by capillary action.

To facilitate transfer of the heat transfer medium by capillary action, a medium with low viscosity may be used as the heat transfer medium.

The supply of the heat transfer medium to the wafer support surface 104E₁ (more specifically, the supply of the heat transfer medium generation gas from the gas supply unit 130E) is stopped when, for example, the supply amount reaches a predetermined amount (more specifically, when the supply time of the heat transfer medium generation gas from the gas supply unit 130E exceeds a predetermined time). For example, a monitor such as a camera may be used to monitor leakage of the heat transfer medium from between the wafer support surface 104E₁ and the back surface of the wafer W. When leakage is detected, the supply of the heat transfer medium to the wafer support surface 104E₁ may be stopped. In this case, the monitor such as a camera located, for example, outside the plasma processing chamber 100 monitors leakage, or specifically, captures images, through the optical window in the plasma processing chamber 100.

Plasma processing is then performed on the wafer W on the wafer support surface 104E₁ on which the heat transfer layer D is formed (step S13). More specifically, plasma processing is performed on the wafer W with the heat transfer layer D between the wafer W and the wafer support surface 104E₁.

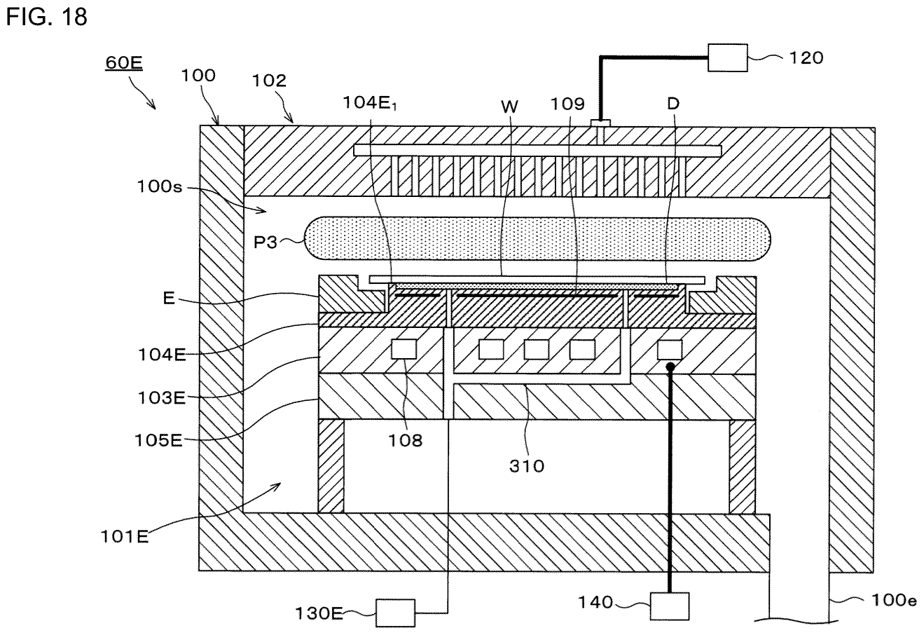

More specifically, as shown in, for example, FIG. 18, a process gas is supplied from the gas supply unit 120 through the upper electrode 102 into the plasma processing space 100s, and RF power HF for plasma generation is provided from the RF power supply unit 140 to the lower electrode 103E, with the wafer W remaining on the wafer support 101E. This excites the process gas and generates plasma P3. In this state, RF power LF for drawing ions may be provided from the RF power supply unit 140. The generated plasma P3 then causes plasma processing on the wafer W.

During plasma processing, the wafer support surface 104E₁ is adjusted to the predetermined temperature T1 with the temperature adjusting fluid flowing through the channel 108 to adjust the temperature of the wafer W. During plasma processing, the wafer W is on the wafer support surface 104E₁ with the heat transfer layer D in between. The heat transfer layer D is deformable as described above, allowing the lower surface, or the back surface, of the wafer W to be in close contact with the heat transfer layer D. The heat transfer layer D is formed from the heat transfer medium including at least one of a liquid medium or a solid medium with fluidity. The heat transfer layer D thus has higher thermal conductivity than a heat transfer gas, such as He. With the heat transfer layer D, the temperature of the wafer W can be adjusted more efficiently with the wafer support surface 104E₁ than when a heat transfer gas, such as He, is supplied to between the wafer support surface 104E₁ and the back surface of the wafer W. More specifically, when a large amount of heat is input from the plasma P3 to the wafer W during plasma processing, the wafer W can be maintained at a constant temperature by adjusting the temperature of the wafer support surface 104E₁. When the set temperature for the wafer W is changed during plasma processing, the temperature of the wafer W can be immediately adjusted to the changed set temperature by adjusting the temperature of the wafer support surface 104E₁.

When the wafer W is held on the wafer support 101E with an electrostatic force during plasma processing, the degree of contact of the wafer W with the wafer support 101E may be controlled using the electrostatic force to control heat removal from the wafer W through the wafer support 101E.

A pressure p3 applied to the heat transfer layer D during plasma processing is 0.1 to 100 Torr, including the pressure applied to the heat transfer layer D by electrostatically clamping the wafer W.

During plasma processing, a DC voltage may be applied to the electrodes for electrostatically clamping the edge ring in the ESC 104. This causes the ESC 104 to electrostatically clamp the edge ring E. During plasma processing, a heat transfer gas may be supplied to the back surface of the edge ring E through gas supply holes (not shown) in the peripheral upper surface 104₂ of the ESC 104.

To end the plasma processing, the supply of the RF power HF from the RF power supply unit 140 and the supply of the process gas from the gas supply unit 120 are stopped. When RF power LF is provided during plasma processing, the supply of the RF power LF is also stopped. The internal space of the plasma processing chamber 100 is then decompressed to a predetermined degree of vacuum (pressure p1) by the exhaust system 150. The above pressure p1 is, for example, less than 0.001 Torr. When the heat transfer gas is supplied to the back surface of the edge ring E, the supply of the heat transfer gas may be stopped.

After plasma processing, the wafer W is separated from the wafer support surface 104E₁, and the heat transfer layer D is removed (step S14). In one example, the heat transfer layer D is removed through vaporization.

More specifically, after the holding of the wafer W on the wafer support 101E (e.g., electrostatic clamping of the wafer W with the ESC 104E) is stopped, the wafer W is raised by the lifters 107 to be separate from the wafer support surface 104E₁, as shown in FIG. 18. Once the wafer W is separated, the heat transfer layer D is exposed to a decompressed atmosphere, or more specifically, to an atmosphere with the pressure p1 of less than 0.001 Torr, thus being vaporized and removed.

To enable such vaporization, the heat transfer medium forming the heat transfer layer D is a liquid or a solid with fluidity at the temperature T1 with the pressure p3 of 0.1 to 100 Torr and a gas at the temperature T1 with the pressure p1 of less than 0.001 Torr.

The heat transfer medium generation gas that forms the heat transfer medium for the heat transfer layer D includes, for example, at least one of boron (B) or carbon (C), which is a constituent atom of the heat transfer layer D, and at least one of hydrogen (H), nitrogen (N), or oxygen (O), which is a gas component. The heat transfer medium generation gas may contain components that do not interfere with plasma processing.

At least one of plasma, heat, or light may be used to remove the heat transfer layer D from the wafer support surface 104E₁, in place of or in addition to exposure to a decompressed atmosphere.

The wafer W is then unloaded (step S15).

More specifically, the wafer W is transferred from the lifters 107 to the transferer 70, and is unloaded from the plasma processing chamber 100 by the transferer 70. This completes the wafer processing.

### Advantageous Effects and Others

In the present embodiment as well, as described above, the heat transfer layer D includes at least one of a liquid layer or a solid layer, and thus has higher thermal conductivity than a heat transfer layer formed from a heat transfer gas. The heat transfer layer D is deformable and can thus be closely in contact with the lower surface of the wafer W. In the present embodiment as well, heat can be efficiently exchanged between the wafer W and the wafer support surface 104E₁ through the heat transfer layer D. The temperature of the wafer W is efficiently adjustable through the wafer support surface 104E₁ during plasma processing.

The heat transfer medium forming the heat transfer layer D includes a liquid or a solid with fluidity, and thus the above heat transfer medium is less likely to clog the channel 310.

In the above example, when the wafer W is separated from the wafer support surface 104E₁, the heat transfer layer D is vaporized and removed. No step for removing the heat transfer layer D is thus used separately, improving throughput.

### Modifications of Heat Transfer Medium Supply

In the above example, the heat transfer medium generation gas is supplied from outside to the wafer support 101E and is converted to a heat transfer medium in the wafer support 101E. In some embodiments, the heat transfer medium may be directly supplied from outside to the wafer support 101.

In the above example, the supply of the heat transfer medium in the wafer support 101E to the wafer support surface 104E₁ is performed by capillary action. In some embodiments, a supply pressure of the heat transfer medium generation gas from outside to the wafer support 101E or the supply pressure of the heat transfer medium from outside to the wafer support 101E may be used to supply the heat transfer medium in the wafer support 101E to the wafer support surface 104E₁.

### Modifications of Heat Transfer Medium

As described above, when the supply pressure of the heat transfer medium from outside to the wafer support 101E is used to supply the heat transfer medium in the wafer support 101E to the wafer support surface 104E₁, any of the heat transfer media described below may be used. For example, a heat transfer medium mixed with a powder with higher thermal conductivity than the base material of the heat transfer medium may be used. The powder with higher thermal conductivity than the base material of the heat transfer medium is, for example, a carbon nanotube powder.

When the supply pressure of the heat transfer medium generation gas from outside to the wafer support 101E is used to supply the heat transfer medium in the wafer support 101E to the wafer support surface 104E₁, a mist including a powder with the thermal conductivity described above may be used as the heat transfer medium generation gas. Cooling the heat transfer medium generation gas in the channel 310 allows the heat transfer medium to be converted to a heat transfer medium mixed with a powder with high thermal conductivity, thus allowing the heat transfer medium to be supplied to the wafer support surface 104E₁.

### Specific Example of Grooves 320

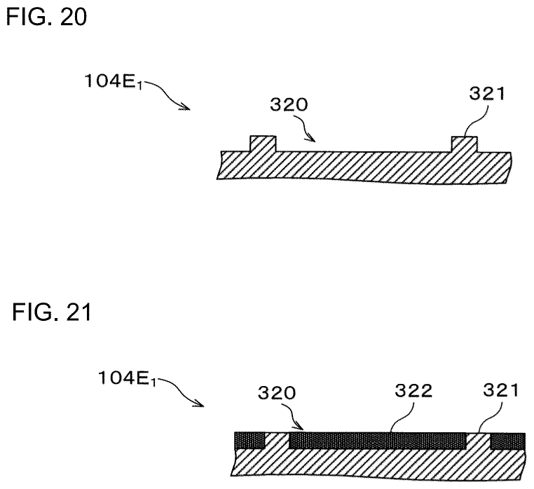

FIGS. 20 and 21 are each a diagram showing a specific example of the grooves 320.

As shown in FIG. 20, the ESC 104E may include, on the wafer support surface 104E₁, multiple support posts 321 that support the back surface of the wafer W. In this case, for example, recesses between the support posts 321 define the grooves 320.

Each groove 320 may be filled with a porous material (more specifically, a porous ceramic material) 322 as shown in FIG. 21. This allows the wafer W to maintain its shape when electrostatically clamped by the ESC 104E, independently of the shape of the groove 320. When the porous material 322 is used, the heat transfer medium flows through the pores in the porous material 322 by capillary action, thus spreading along the wafer support surface 104E₁.

### Other Examples of Wafer Support Surfaces in Second Embodiment

In the present embodiment, the wafer support surface may include portions formed from a porous material located other than the grooves 320 (more specifically, for example, the top of the support posts 321). When the grooves 320 are not located on the wafer support surface, the wafer support surface may be entirely formed from the porous material.

### Example Heat Transfer Layer D on Wafer Support Surface 104E₁

In the present embodiment as well, the heat transfer layer D is formed on the entire wafer support surface 104E₁, including, for example, the central area and the peripheral area of the wafer support surface 104E₁. In some embodiments, the heat transfer layer D may be formed on a part of the wafer support surface 104E₁. For example, the heat transfer layer D may be formed on the central area or on the peripheral area of the wafer support surface 104E₁. For example, the grooves 320 may be located in an area, for example, the central area, on the wafer support surface 104E₁. This allows the heat transfer layer D to be formed on the area.

In the present embodiment as well, the heat transfer layer D has uniform thickness across the entire wafer support surface 104E₁, including, for example, the central area and the peripheral area of the wafer support surface 104E₁. In some embodiments, the thickness may vary within the plane of the wafer support surface 104E₁. For example, the heat transfer layer D may be thinner in the central area or the peripheral area of the wafer support surface 104E₁. Thus, the heat exchange efficiency between the wafer support surface 104E₁ and the wafer W may vary within the plane, or the heat exchange efficiency may be increased in the above area.

When the grooves 320 are located on the wafer support surface 104E₁, the grooves 320 may have different depths in different areas on the wafer support surface 104E₁, allowing the heat transfer layer D to be thinner in an area, for example, the central area.

When the grooves 320 are not located on the wafer surface support 104E₁ and the wafer support surface 104E₁ is entirely formed from a porous material, the porous material may have different thicknesses in different areas on the wafer support surface 104E₁. This also allows the heat exchange efficiency between the wafer support surface 104E₁ and the wafer W to vary within the plane, as in the structure with the grooves 320 having different depths in different areas on the wafer support surface 104E₁.

The heat transfer layer D may be formed from a conductive medium with high thermal conductivity and a conductive medium with a low thermal conductivity mixed together. In this case, the mixing ratio of these conductive media may be different in different areas on the wafer support surface 104E₁. This also allows the heat exchange efficiency between the wafer support surface 104E₁ and the wafer W to vary within the plane.

The density of the grooves 320 may be different in different areas on the wafer support surface 104E₁. In other words, when the recesses between the support posts 321 define the grooves 320, the density of the support posts 321 may be different in different areas on the wafer support surface 104E₁. This also allows the heat exchange efficiency between the wafer support surface 104E₁ and the wafer W to vary within the plane.

### Modifications of Second Embodiment

In the above example, the heat transfer layer D is formed after the wafer W is placed on the wafer support surface 104E₁. In some embodiments, the heat transfer layer D may be formed before the wafer W is placed on the wafer support surface 104E₁. In this case, however, a medium that is at least one of a liquid and a solid is used as the heat transfer medium on the wafer support surface 104E₁ when no wafer W is located on the surface.

In this case, the wafer W may be located in the plasma processing chamber 100 and separate from the wafer support surface 104E₁ when forming the heat transfer layer D, as in the example described with reference to FIG. 13.

### Third Embodiment

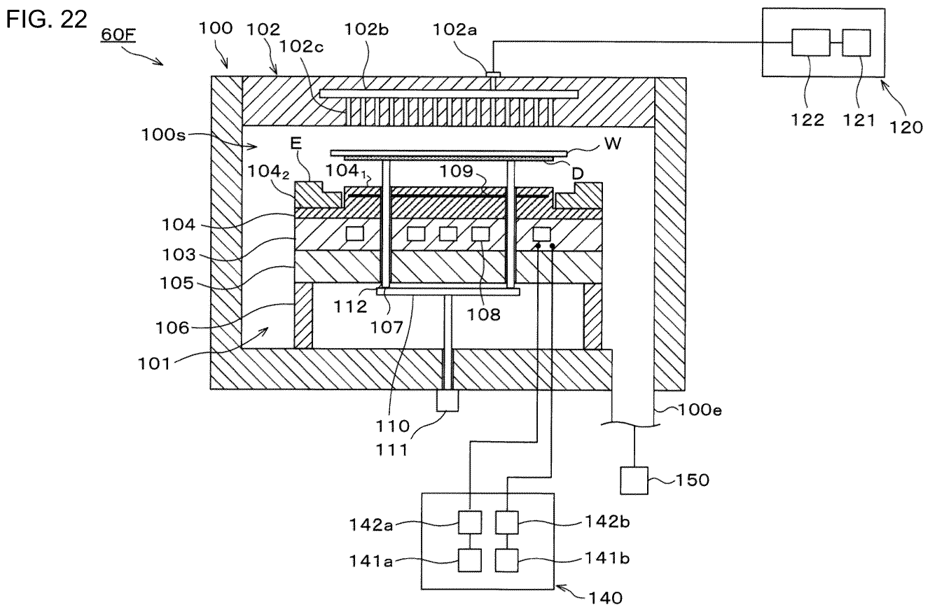

FIG. 22 is a schematic longitudinal cross-sectional view of a processing module as a plasma processing apparatus according to a third embodiment.

Unlike the processing module 60 in FIG. 2, no raw gas for the heat transfer layer D is supplied into a processing module 60F in FIG. 22, and unlike the processing module 60E in FIG. 14, no heat transfer medium that forms the heat transfer layer D is supplied through the wafer support 101.

In the processing module 60F in FIG. 22, a deformable heat transfer layer D, which includes a liquid layer or a solid layer, is formed on the wafer support surface 104₁ of the wafer support 101 as described below.

The controller 80 controls, for example, the lifters 107 to place the wafer W with the heat transfer layer D preformed on the back surface onto the wafer support surface 104₁ of the wafer support 101, thus forming the heat transfer layer D on the wafer support surface 104₁.

In the present embodiment, the controller 80 and the lift assembly including the lifters 107 for the wafer W may serve as at least a part of a heat transfer layer formation unit to form the heat transfer layer D on the wafer support surface 104₁.

The preforming of the heat transfer layer D on the lower surface of the wafer W is performed in, for example, the transfer module 50, the loadlock module 20 or 21, or the loader module 30. For the above preforming, for example, a gas that liquefies or solidifies at a predetermined temperature or lower is used to cool the lower surface of the wafer W to the predetermined temperature or lower, thus preforming the heat transfer layer D on the lower surface of the wafer W. A wafer W with the heat transfer layer D preformed on the lower surface outside the plasma processing system 1 may be stored in the FOUP 31, and the wafer W may be used.

In the present embodiment as well, heat can be efficiently exchanged between the wafer W and the wafer support surface 104₁ through the heat transfer layer D. Thus, in the present embodiment as well, the temperature of the wafer W is efficiently adjustable through the wafer support surface 104₁ during plasma processing.

In the present embodiment, the heat transfer layer D may be formed on the entire back surface of the wafer W or on either the central area or the peripheral area of the back surface of the wafer W. The heat transfer layer D may include a filler (a powder in one example) with higher thermal conductivity than the base material.

### Fourth Embodiment

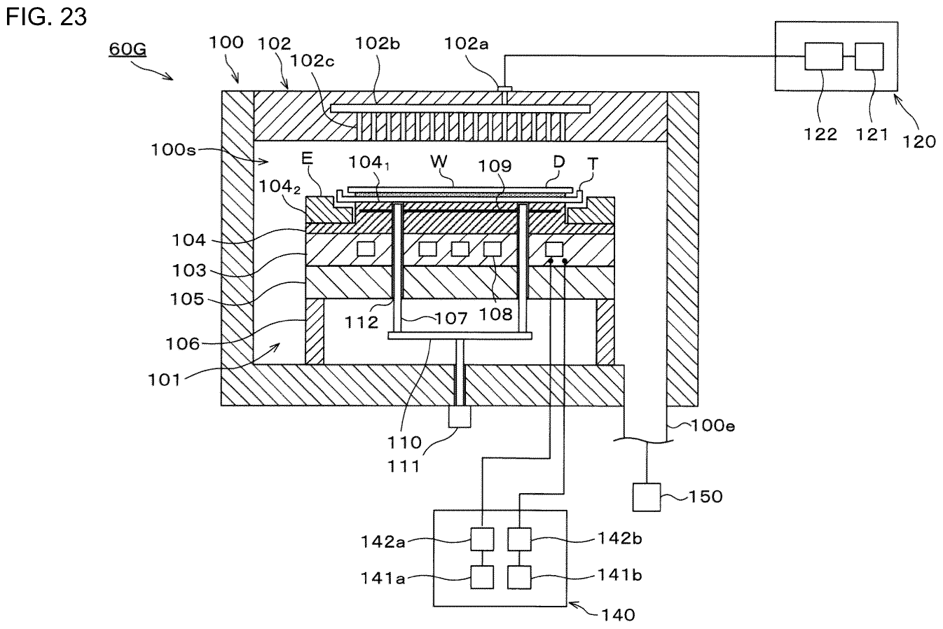

FIG. 23 is a schematic longitudinal cross-sectional view of a processing module as a plasma processing apparatus according to a fourth embodiment.

Similarly to the processing module 60F in FIG. 22, no raw gas for the heat transfer layer D is supplied into a processing module 60G in FIG. 23, and no heat transfer medium that forms the heat transfer layer D is supplied through the wafer support 101.

In the processing module 60G in FIG. 23, a deformable heat transfer layer D, which includes a liquid layer or a solid layer, is formed on the wafer support surface 104₁ of the wafer support 101 as described below.

The controller 80 controls, for example, the lifters 107 to place a tray T with the heat transfer layer D between the wafer W and the tray T onto the wafer support surface 104₁ of the wafer support 101, thus forming the heat transfer layer D on the wafer support surface 104₁ through the tray T.

In the present embodiment as well, the controller 80 and the lift assembly including the lifters 107 for the wafer W may serve as at least a part of a heat transfer layer formation unit to form the heat transfer layer D on the wafer support surface 104₁.

The tray T receiving the wafer W with, for example, the heat transfer layer D in between, may be stored in the FOUP 31.

In the present embodiment, the heat transfer layer D may be formed on the entire back surface of the wafer W as in the third embodiment, or on either the central area or the peripheral area of the back surface of the wafer W. The heat transfer layer D may include a filler (a powder in one example) with higher thermal conductivity than the base material.

The tray T is formed from, for example, the same material as the edge ring E.

When plasma etching is performed as plasma processing in the processing module 60G, trays T formed from different materials may be used depending on the material of the layer to be etched.

The tray T may have a thickness optimized for an intended height of the edge of the wafer W.

The tray T may have an area facing the wafer W and the other areas that are electrically isolated from each other.

In the present embodiment, a heat transfer layer similar to the heat transfer layer D may be formed between the tray T and the wafer support surface 104₁. The heat transfer layer can be formed in the same manner as the heat transfer layer D.

### Modifications of First to Fourth Embodiments

The wafer support surface of the wafer support may have a uniform height between the central area and the peripheral area, or may be macroscopically flat. In some embodiments, the wafer support surface may be higher in the central area or higher in the peripheral area.

For the wafer support surface with a convex shape having a higher central area, a wafer W having a higher temperature than the wafer support surface may be placed onto the wafer support surface and cooled from the back surface to thermally deform into a convex shape. The wafer W and the wafer support surface can then come in close contact with each other.

For the wafer support surface with a concave shape having a lower central area, a wafer W having a lower temperature than the wafer support surface may be placed onto the wafer support surface and heated from the back surface to thermally deform into a concave shape. The wafer W and the wafer support surface can then come in close contact with each other.

When the tray T is used as in the fourth embodiment, the tray T and the wafer support surface can come in close contact with each other in the same manner.

As described above, the heat transfer layer D may be formed on the entire wafer support surface or the back surface of the wafer W, or on a part of the wafer support surface or the back surface of the wafer W (more specifically, either the central area or the peripheral area). A heat transfer gas, such as a He gas, may be supplied to an area of the wafer support surface or the back surface of the wafer W without the heat transfer layer D.

In the above example, an ESC is used as a fastener that holds or fastens the wafer W on the wafer support surface. The ESC electrostatically clamps the wafer W with an electrostatic force generated by a DC voltage applied to the internal electrode 109.

The fastener that electrically holds or fastens the wafer W may not use an electrostatic force. In some embodiments, the fastener may hold the wafer W with a Johnsen-Rahbek force.

The above fastener may hold the wafer W in any manner other than the electrical manner described above. For example, the above fastener may be a fastener, such as a clamp, to physically hold the wafer W. The clamp holds and fastens the wafer W between the clamp and the wafer support.

The above fastener may be eliminated.

### Electrical Characteristics of Heat Transfer Layer D

The heat transfer layer D may be electrically insulating. The heat transfer layer D thus has a residual charge, which can be used for electrostatically clamping the wafer W.

The heat transfer layer D may be conductive. The heat transfer layer D can thus remove a residual charge on the wafer W.

The heat transfer layer D may include a conductive portion surrounded by an electrically insulating portion. This structure allows high thermal conductivity in the conductive portion and electrostatic clamping of the wafer W in the electrically insulating portion with the residual charge generated in the electrically insulating portion.

### Fifth Embodiment

### Plasma Processing System

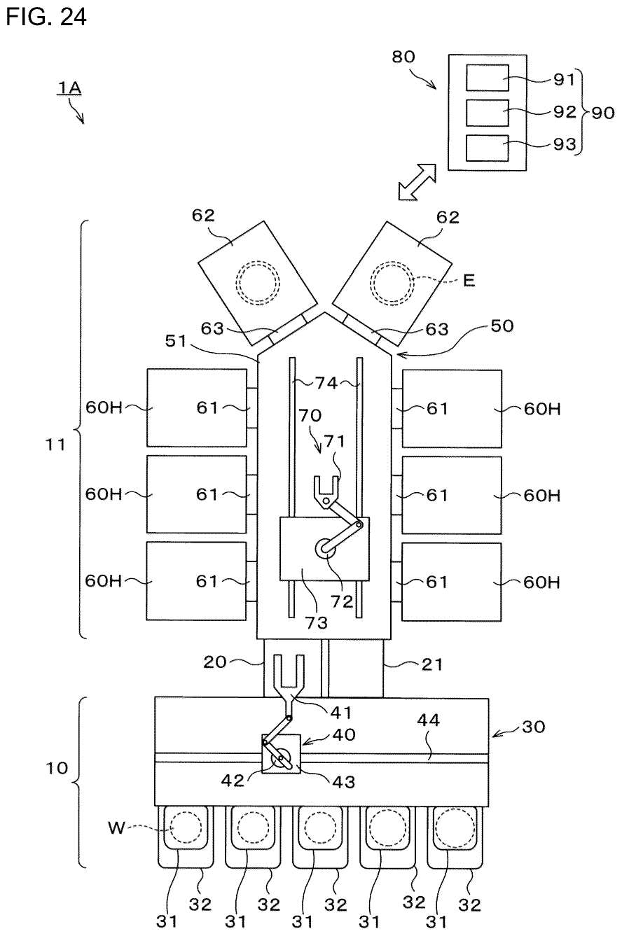

FIG. 24 is a schematic plan view of a plasma processing system including a processing module as a plasma processing apparatus according to a fifth embodiment.

A plasma processing system 1A in FIG. 24 includes, in addition to the transfer module 50, a decompressor 11 including processing modules 60H as plasma processing apparatuses and storage modules 62 as storages that store the edge rings E. The internal spaces of the processing modules 60H (more specifically, the internal space of the plasma processing chamber 100) and the internal spaces of the storage modules 62 are maintained in a decompressed atmosphere. The single transfer module 50 receives multiple (e.g., six) processing modules 60H and multiple (e.g., two) storage modules 62.

Each processing module 60H is connected to the transfer module 50 with a gate valve 61. The differences between the processing modules 60H and the processing modules 60 in FIG. 1 will be described later.

Each storage module 62 is connected to the transfer module 50 with a gate valve 63.

In the present embodiment, the transfer module 50 transfers a wafer W as well as an edge ring E. More specifically, the transfer module 50 transfers an edge ring E in the storage module 62 to one processing module 60H and also unloads an edge ring E to be replaced in the processing module 60H to the storage module 62.

The transferer 70 can transfer a wafer W and an edge rings E. The transferer 70 includes a transfer arm 71 that can support a wafer W as well as an edge ring E.

In the transfer module 50, the transfer arm 71 receives an edge ring E from the storage module 62 and loads the edge ring E into the processing module 60H. The transfer arm 71 also receives an edge ring E held in the processing module 60H and unloads the edge ring E to the storage module 62.

The wafer processing performed in the plasma processing system 1A is similar to the wafer processing performed in the plasma processing system 1 shown in FIG. 1, and thus will not be described.

### Processing Module 60H

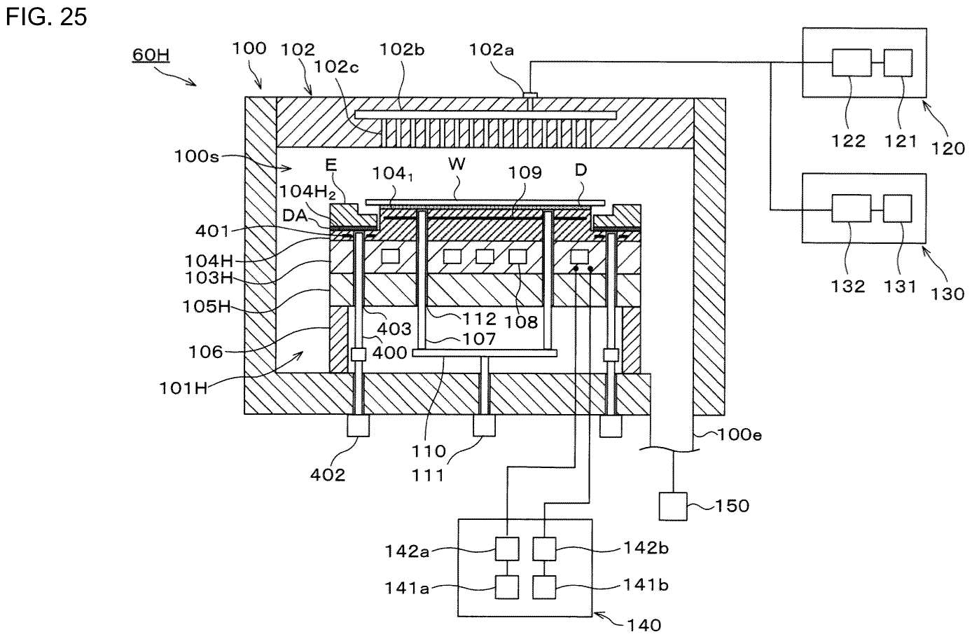

FIG. 25 is a schematic longitudinal cross-sectional view of the processing module 60H.

In the processing module 60 in FIG. 2 and other modules, the wafer W undergoes temperature adjustment through the wafer support and the deformable heat transfer layer D as described above. In contrast, in the processing module 60H in FIG. 25, the wafer W as well as the edge ring E undergo temperature adjustment through the wafer support and the deformable heat transfer layer. The processing module 60H in FIG. 25 thus differs from the processing module 60 in FIG. 2 and other modules mainly in the structure of the wafer support. The processing module 60H will be described focusing on the difference.

The processing module 60H includes a wafer support 101H including, for example, a lower electrode 103H, an ESC 104H, an insulator 105H, legs 106, and lifters 107 and 400.

Similarly to the ESC 104 in FIG. 2, the ESC 104H has a wafer support surface 104₁ in a center portion and a peripheral upper surface 104H₂ serving as a ring support surface on which an edge ring E is placeable.

The ESC 104H is an example fastener that fastens the edge ring E to the peripheral upper surface 104H₂ of the ESC 104H, or in other words, the ring support surface. The ESC 104H includes an electrode 109 in the center portion to electrostatically clamp the wafer W and an electrode 401 in the periphery to electrostatically clamp the edge ring E.

The electrode 401 receives a DC voltage from a DC power supply (not shown). This generates an electrostatic force for electrostatically clamping the edge ring E onto the peripheral upper surface 104H₂ of the ESC 104H (hereafter, a ring support surface). The electrode 401 is, for example, bipolar including a pair of electrodes, but may also be monopolar.

Each lifter 400 is, for example, a cylindrical lifter that ascends and descends relative to the ring support surface 104H₂ of the ESC 104H. When the lifter 400 ascends, its upper end protrudes from the ring support surface 104H₂ to support the edge ring E. The lifters 400 allow transfer of the edge ring E between the ESC 104H and the transfer arm 71 in the transferer 70.

Three or more lifters 400 are spaced from one another in the circumferential direction of the ESC 104H. Each lifter 400 extends in the vertical direction.

Each lifter 400 is connected to a drive 402 that raises and lowers the lifter 400. The drive 402 is, for example, provided for each lifter 400. The drive 402 includes, for example, a motor (not shown) as a drive source that generates a driving force to raise and lower the lifter 400.

Each lifter 400 is placed through a through-hole 403 having the upper end that is open in the ring support surface 104H₂ of the ESC 104H. The through-hole 403 extends through, for example, the periphery of the ESC 104H, the lower electrode 103H, and the insulator 105H.

In the processing module 60H, a heat transfer layer DA being liquid is formed on, for example, the ring support surface 104H₂ of the wafer support 101H from the gas including the raw gas supplied from a gas supply unit 130. In the processing module 60H, the gas supply unit 130 may thus serve as at least a part of a heat transfer layer formation unit to form the heat transfer layer DA on the ring support surface 104H₂.

In the processing module 60H, plasma may be generated from the raw gas as the material for the heat transfer layer DA supplied into the plasma processing space 100s with RF power provided from the RF power supply unit 140. The RF power supply unit 140 may thus serve as at least a part of another plasma generator for generating plasma from a raw gas in the plasma processing chamber 100.

### Wafer Processing in Processing Modules 60H

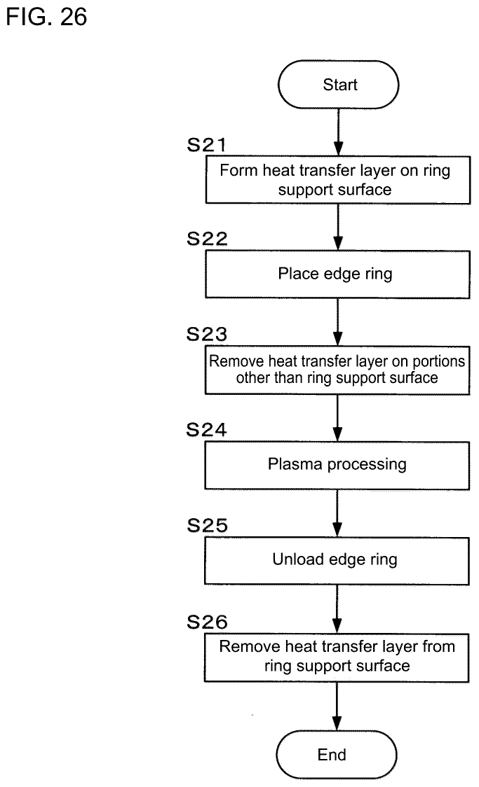

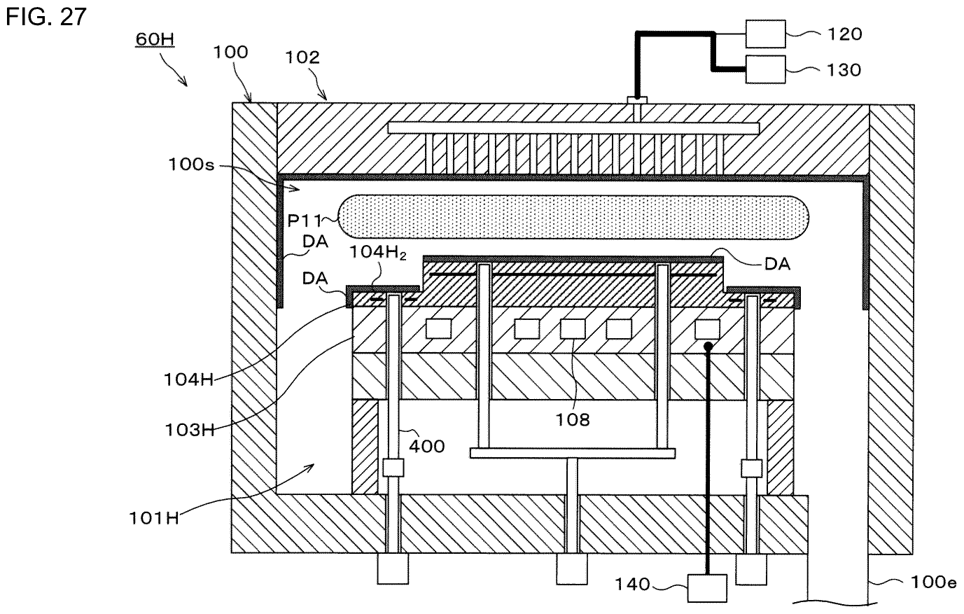

Example wafer processing including a process of replacing the edge ring E and performed in the processing module 60H will now be described with reference to FIGS. 26 to 30. FIG. 26 is a flowchart of example wafer processing. FIGS. 27 to 30 are each a diagram of the processing module 60H in a processing state during the wafer processing. The processing described below is performed under the control of the controller 80.

As shown in, for example, FIG. 26, a heat transfer layer DA is formed on the ring support surface 104H₂ of the wafer support 101H (step S21).

More specifically, as shown in FIG. 27, without the wafer W and the edge ring E on the wafer support 101H, a gas including a raw gas for the heat transfer layer DA being liquid is first supplied from the gas supply unit 130 through the upper electrode 102 into the plasma processing chamber 100, which is decompressed to a predetermined degree of vacuum by the exhaust system 150. Simultaneously, RF power HF for plasma generation is provided from the RF power supply unit 140 to the lower electrode 103. This excites the raw gas and generates plasma P11. The generated plasma P11 then causes the heat transfer layer DA being liquid to form on, for example, the ring support surface 104H₂. After the formation of the heat transfer layer DA, the supply of RF power HF from the RF power supply unit 140 and the supply of gas including the raw gas from the gas supply unit 130 are stopped.

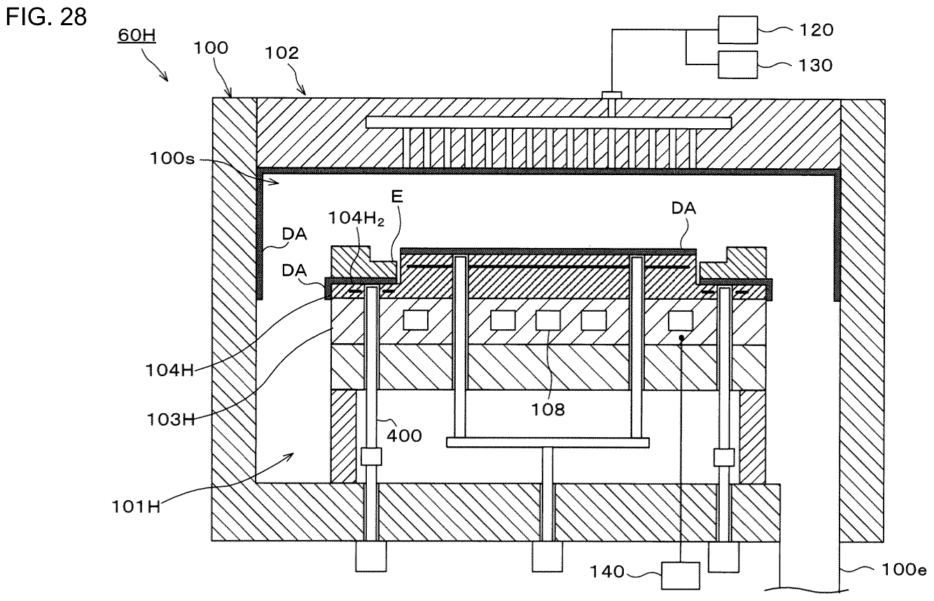

As shown in FIG. 28, an edge ring E is then placed onto the ring support surface 104H₂ of the wafer support 101H (step S22).

More specifically, the edge ring E is loaded into the plasma processing chamber 100 by the transferer 70, and is placed onto the ring support surface 104H₂ of the ESC 104H by using the lifters 400 that can ascend or descend. The internal space of the plasma processing chamber 100 is then decompressed to a predetermined degree of vacuum by the exhaust system 150.

The edge ring E is transferred into the plasma processing chamber 100 in, for example, the manner described below.

First, an edge ring E in the storage module 62 is held by the transfer arm 71 in the transferer 70. The transfer arm 71 holding the edge ring E is then placed into the plasma processing chamber 100 in the processing module 60H through a port (not shown). The edge ring E is then transferred by the transfer arm 71 to above the ring support surface 104₂ of the ESC 104H.

The edge ring E is placed onto the ring support surface 104H₂ of the ESC 104H with the lifters 400 that can ascend and descend and the transfer arm 71 pulled out of the plasma processing chamber 100.

The heat transfer layer DA formed on portions in the plasma processing chamber 100 other than the ring support surface 104H₁ is then removed (step S23).

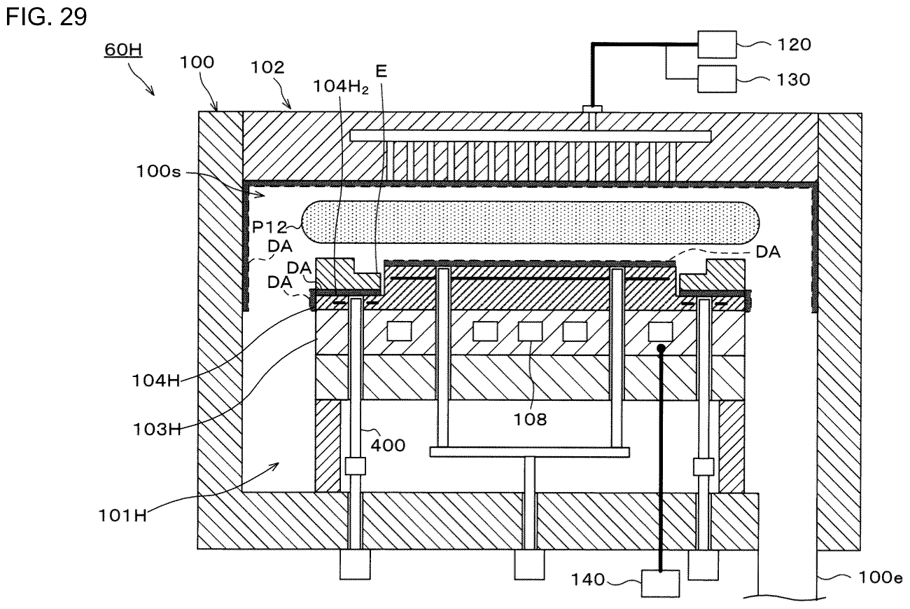

More specifically, as shown in FIG. 29, a removal gas for removing the heat transfer layer DA is supplied from the gas supply unit 120 through the upper electrode 102 into the plasma processing space 100s, and RF power HF for plasma generation is provided from the RF power supply unit 140 to the lower electrode 103H. This excites the removal gas and generates plasma P12. The generated plasma P12 then removes the heat transfer layer DA formed on the portions other than the ring support surface 104H₂ (e.g., the inner wall surface of the plasma processing chamber 100 such as the lower surface of the upper electrode 102 and the wafer support surface 104₁). The heat transfer layer DA on the ring support surface 104H₂ is covered with the wafer W and is not exposed to the plasma P12, remaining without being removed. After the removal of the heat transfer layer DA, the supply of RF power HF from the RF power supply unit 140 and the supply of the removal gas from the gas supply unit 120 are stopped.

Plasma processing is then performed on the wafer W on the upper surface, or the support surface, of the ESC 104H on which the heat transfer layer DA is formed (step S24).

More specifically, for example, plasma processing is performed in the same manner as the processing described with reference to FIG. 3 and other figures. More specifically, for example, after the heat transfer layer D is formed on the wafer support surface 104₁ of the wafer support 101H, the wafer W is placed onto the wafer support surface 104₁, and plasma processing is then performed on the wafer W. The wafer W is then unloaded. After unloading, the heat transfer layer D may be removed from the wafer support surface 104₁.

During plasma processing, the ring support surface 104H₂ is adjusted to a predetermined temperature with the temperature adjusting fluid flowing through the channel 108 to adjust the temperature of the edge ring E. During plasma processing, the edge ring E is placed on the ring support surface 104H₂ with the heat transfer layer DA in between. The heat transfer layer DA is deformable, allowing the lower surface, or the back surface, of the edge ring E to be in close contact with the heat transfer layer DA. The heat transfer layer DA being a liquid has higher thermal conductivity than a heat transfer gas, such as He. With the heat transfer layer DA being liquid, the temperature of the edge ring E can be adjusted more efficiently through the ring support surface 104H₂ than when a heat transfer gas, such as He, is supplied to between the ring support 104H₂ and the back surface of the edge ring E. More specifically, when a large amount of heat is input from the plasma P to the edge ring E during plasma processing, the edge ring E can be maintained at a constant temperature by adjusting the temperature of the ring support surface 104H₂. When the set temperature of the edge ring E is changed during plasma processing, the temperature of the edge ring E can be immediately adjusted to the changed set temperature by adjusting the temperature of the ring support surface 104H₂.

During plasma processing, the edge ring E may be held, or fastened, to the wafer support 101H (more specifically, the ring support surface 104H₂) to place the heat transfer layer DA and the lower surface of the edge ring E into closer contact. For example, the edge ring E may be electrostatically clamped onto the ring support surface 104H₂ with an electrostatic force from the ESC 104H. More specifically, a DC voltage may be applied to the electrode 401 in the ESC 104H to cause the ESC 104H to electrostatically clamp the edge ring E with an electrostatic force. The temperature of the edge ring E held as described above can be adjusted more efficiently.

The edge ring E may be held on the wafer support 101H with, for example, an electrostatic force during the removal process of the heat transfer layer DA in step S13.

When the edge ring E is held on the wafer support 101H under an electrostatic force, the degree of contact of the edge ring E with the wafer support 101H may be controlled using the electrostatic force to control heat removal from the edge ring E through the wafer support 101H.

After plasma processing on the wafer W, the edge ring E is separated from the ring support surface 104H₂ and unloaded (step S25). The separation of the edge ring E from the ring support surface 104H₂, or the removal of the edge ring E, may not be performed every time the plasma processing is performed on the wafer W, but may be performed when the edge ring E is worn or when the heat transfer layer DA is damaged or worn by plasma.

In step S25, more specifically, the edge ring E is raised by the lifters 400 to be separate from the heat transfer layer DA on the ring support surface 104H₂. The edge ring E is then transferred from the lifters 400 to the transferer 70, and is unloaded from the plasma processing chamber 100 by the transferer 70.

The heat transfer layer DA is then removed from the ring support surface 104H₂ (step S26).

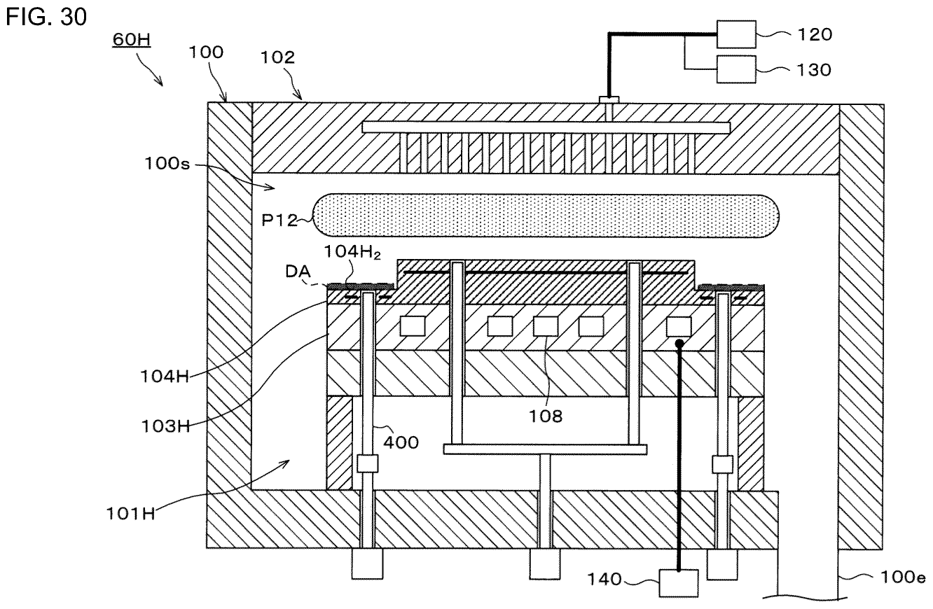

More specifically, as shown in FIG. 30, the removal gas for removing the heat transfer layer DA is supplied from the gas supply unit 120 through the upper electrode 102 into the plasma processing space 100s, and RF power HF for plasma generation is provided from the RF power supply unit 140 to the lower electrode 103H. This excites the removal gas and generates the plasma P12. The generated plasma P12 then removes the heat transfer layer DA from the ring support surface 104H₂. After the removal of the heat transfer layer DA, the supply of RF power HF from the RF power supply unit 140 and the supply of the removal gas from the gas supply unit 120 are stopped.

The processing then returns to step S21, and steps S22 and S23 are performed to form a heat transfer layer DA on the ring support surface 104H₂, and a new edge ring E is placed onto the ring support surface 104H₂.

The heat transfer layer DA may not be removed from the ring support surface 104H₂ in step S26 for each edge ring E. In other words, the heat transfer layer DA on the ring support surface 104H₂ may be used for multiple edge rings E.

### Other Examples of Heat Transfer Layer DA

In the above example, the heat transfer layer DA for the edge ring E is a liquid layer. However, the heat transfer layer DA may be a solid layer when it is deformable.

The heat transfer layer DA may be a combination of a liquid layer and a solid layer when it is deformable.

In other words, the heat transfer layer DA for the edge ring E is, similarly to the heat transfer layer D for the wafer W, a deformable layer including at least one of a liquid layer or a solid layer.

The heat transfer layer DA for the edge ring E may be the same as or different from the heat transfer layer D for the wafer W.

### Advantageous Effects and Others

In the present embodiment, as described above, a deformable heat transfer layer DA including at least one of a liquid layer or a solid layer is formed on the wafer support surface 104₁ of the wafer support 101. In the present embodiment, the temperature of the edge ring E is efficiently adjustable through the ring support surface 104H₂ during plasma processing, as in the first embodiment.

In the present embodiment, as described above, the edge ring E may be electrostatically clamped onto the ring support surface 104H₂ with an electrostatic force from the ESC 104H during plasma processing. This allows the heat transfer layer DA and the lower surface of the edge ring E to be in closer contact with each other, further improving the efficiency of heat removal from the edge ring E or the efficiency of heating the edge ring E through the ring support surface 104H₂ and the heat transfer layer DA.

Example State and Electrical Characteristics of heat transfer Layer DA on Ring Support Surface 104H₂

The heat transfer layer DA for the edge ring E may be, similarly to the heat transfer layer D for the wafer W, formed on the entire ring support surface 104H₂, or on a part of the ring support surface 104H₂. For example, the heat transfer layer DA may be formed adjacent to the inner periphery of the ring support surface 104H₂, or may be formed adjacent to the outer periphery of the ring support surface 104₂.

The heat transfer layer DA for edge ring E may have, similarly to the heat transfer layer D for the wafer W, different thicknesses in the plane of the ring support surface 104H₂. For example, the heat transfer layer DA may be thinner adjacent to the inner periphery than adjacent to the outer periphery of the ring support surface 104H₂, or may be thinner adjacent to the outer periphery than adjacent to the inner periphery of the ring support surface 104H₂.

The heat transfer layer DA may be formed on a part of the ring support surface 104H₂. A heat transfer gas, such as a He gas, may be supplied to an area of the ring support surface 104H₂ without the heat transfer layer DA.

The heat transfer layer DA for the edge ring E may be electrically insulating.

The heat transfer layer DA may be conductive.

The heat transfer layer DA may include a conductive portion surrounded by an electrically insulating portion.

### Modifications of Fifth Embodiment

In the example described with reference to FIG. 3 and other figures, the wafer W alone, of the wafer W and the edge ring E, undergoes temperature adjustment through the wafer support 101 and the heat transfer layer D in the processing module 60 in FIG. 2. In the example described with reference to FIG. 26 and other figures, both the wafer W and the edge ring E undergo temperature adjustment through the wafer support 101H and the heat transfer layer D in the processing module 60H in FIG. 25. However, the edge ring E alone, of the wafer W and the edge ring E, may undergo temperature adjustment through the wafer support 101H and the heat transfer layer D in the processing module 60H in FIG. 25. In other words, in the processing module 60H in FIG. 25, the heat transfer layer DA for the edge ring E may be formed alone without forming the heat transfer layer D for the wafer W.

In the example described above with reference to FIG. 26 and other figures, both the wafer W and the edge ring E undergo the above temperature adjustment, and the heat transfer layer D for the wafer W is formed at a time different from the time at which the heat transfer layer DA for the edge ring E is formed. However, when the heat transfer layer D for the wafer W and the heat transfer layer DA for the edge ring E are the same, the heat transfer layer D for the wafer W may be formed at the same time as the heat transfer layer DA for the edge ring E, improving throughput.

When the heat transfer layer D for the wafer W and the heat transfer layer DA for the edge ring E are formed at time different times, a dummy wafer may be placed on the wafer support surface 104₁ when the heat transfer layer DA for the edge ring E is formed.

In the example described above with reference to FIG. 26 and other figures, the heat transfer layer D for the wafer W is removed at a time different from the time at which the heat transfer layer DA for the edge ring E is removed. However, when the edge ring E is also replaced when the wafer W is replaced, the heat transfer layer D for the wafer W may be removed at the same time as the heat transfer layer DA for the edge ring E, improving throughput.

The heat transfer layer DA for the edge ring E may be formed from a raw gas in any manner other than in the above example. Modifications similar to those in forming the heat transfer layer D for the wafer from a raw gas described above may be applied.

The raw gas for the heat transfer layer DA for the edge ring E may be supplied into the plasma processing space 100s in any manner other than in the above example. Modifications similar to those in supplying the raw gas for the heat transfer layer D for the wafer into the plasma processing space 100s described above may be applied.

The heat transfer layer DA formed on the portions other than the ring support surface 104H₂ may be removed in any manner other than in the above example. Modifications similar to those in removing the heat transfer layer D formed on the portions other than the above wafer support surface may be applied.

The heat transfer layer DA formed on the ring support surface 104H₂ may be removed in any manner other than in the above example. Modifications similar to those in removing the heat transfer layer D formed on the above wafer support surface may be applied.

In the above example, the edge ring E is not located in the plasma processing chamber 100 during formation of the heat transfer layer DA for the edge ring E. In some embodiments, the edge ring E may be located in the plasma processing chamber 100 during formation.

More specifically, the edge ring E may be located in the plasma processing chamber 100 and separate from the ring support surface 104H₂ during formation of the heat transfer layer DA. More specifically, with the wafer W supported by the lifters 400 and separate from the ring support surface 104H₂, the raw gas may be supplied into the plasma processing chamber 100 and liquefy or solidify, thus forming the heat transfer layer DA on the ring support surface 104H₂.

In this case, the heat transfer layer DA formed on the upper surface of the edge ring E when the heat transfer layer DA is formed on the ring support surface 104H₂ may be removed in, for example, the manner described below. The heat transfer layer DA formed on the upper surface of the edge ring E may be removed in the same manner as when the heat transfer layer D formed on the upper surface of the wafer W is removed as described with reference to FIG. 13.

When the heat transfer layer DA is formed with the edge ring E supported by the lifters 400 to be separate from the ring support surface 104H₂, as described in this example, a restrictor may restrict the formation of the heat transfer layer DA on the lifters 400. The above restrictor has, for example, the same structure as the restrictor for restricting the formation of the heat transfer layer D for the wafer W on the lifters 107.

In some embodiments, the heat transfer layer DA may be formed on the ring support surface 104H₂ as described below.

The raw gas supplied into the plasma processing chamber 100 may at least liquefy or solidify to form the heat transfer layer DA at least on the lower surface of the edge ring E in the plasma processing chamber 100, without forming the heat transfer layer DA on the ring support surface 104H₂. The edge ring E receiving the heat transfer layer DA on its lower surface may then be placed onto the ring support surface 104H₂, thus forming the heat transfer layer DA on the ring support surface 104H₂.

In this example, the controller 80, the lift assembly including the lifters 400 for the edge ring E, and the gas supply unit 130 may serve as at least a part of a heat transfer layer formation unit to form the heat transfer layer DA on the ring support surface 104H₂.

To selectively form the heat transfer layer DA on the edge ring E as described above, for example, the edge ring E may be pre-cooled before being loaded into the plasma processing chamber 100. When the edge ring E is pre-cooled in this manner, the lifters 400 for supporting the edge ring E may have its distal end, or an upper end, formed from an insulating material.

In the above example, when the heat transfer layer DA for the edge ring E is removed from the ring support surface 104H₂ and the heat transfer layer DA is formed on the ring support surface 104H₂, the edge ring E is also replaced. In some embodiments, the edge ring may not be replaced. When not replaced, the edge ring E may be located outside the plasma processing chamber 100 during formation of the heat transfer layer DA on the ring support 104H₂, or the edge ring E may be located in the plasma processing chamber 100 and supported by the lifters 400 during formation to be separate from the ring support surface 104H₂.

### Sixth Embodiment

### Processing Module 60J

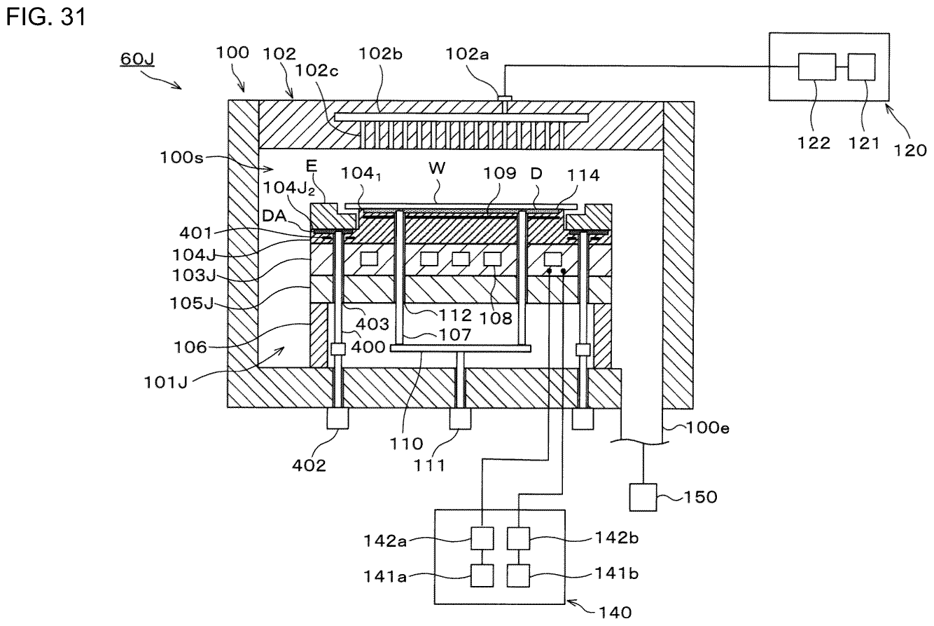

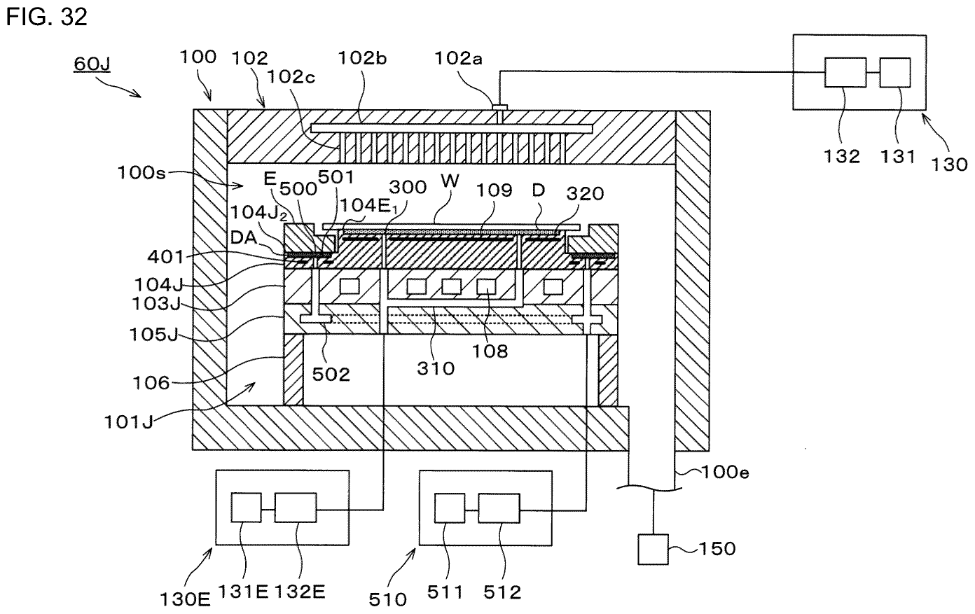

FIGS. 31 and 32 are each a schematic longitudinal cross-sectional view of a processing module as a plasma processing apparatus according to a sixth embodiment. FIGS. 31 and 32 show the wafer support 101J in a cross section focusing on the components different from each other.

In the present embodiment, as in the second embodiment, the heat transfer layer D is formed on the wafer support from a heat transfer medium including at least one of a liquid medium or a solid medium with fluidity. In the second embodiment, the wafer W undergoes temperature adjustment through the wafer support and the heat transfer layer D. In the present embodiment, the wafer W as well as the edge ring E undergo the above temperature adjustment. The processing module in the present embodiment thus differs from the processing module in the second embodiment mainly in the structure of the wafer support. The processing module 60J will be described focusing on the difference.

The processing module 60J in FIGS. 31 and 32 includes a wafer support 101J including, for example, a lower electrode 103J, an ESC 104J, an insulator 105J, legs 106, and lifters 107 and 400.

The ESC 104J includes an electrode 109 and an electrode 401, similarly to the ESC 104H in FIG. 25.

In the processing module 60J, a through-hole 403 receiving the lifter 400 extends through, for example, the periphery of the ESC 104J, the lower electrode 103J, and the insulator 105J.

As shown in FIG. 32, supply ports 500 for the heat transfer medium is located in the ring support surface 104J₂ of the ESC 104J in the wafer support 101J. For example, multiple supply ports 500 are located in the ring support surface 104J₂.

The ring support surface 104J₂ may have grooves 501. The grooves 501 allow the heat transfer medium to flow and spread along the ring support surface 104J₂.

A channel 502 is located in the wafer support 101J. The channel 502 has its ends connected to the respective supply ports 500 to allow fluid passage. The channel 502 has another end, opposite to these ends, that is fluidly connected to, for example, a gas supply unit 510. The channel 502 has, for example, thinner ends adjacent to the ring support surface 104J₂ (more specifically, for example, a portion inside the ESC 104J). The heat transfer medium in the channel 502 is supplied to the ring support surface 104J₂ by capillary action through the supply ports 500. The channel 502 extends through, for example, the ESC 104J, the lower electrode 103J, and the insulator 105J.

The gas supply unit 510 may include one or more gas sources 511 and one or more flow controllers 512. In one embodiment, the gas supply unit 510 supplies, for example, one or more heat transfer medium generation gases from the respective gas sources 511 to the wafer support 101J through the corresponding flow controllers 512. Each flow controller 512 may include, for example, a mass flow controller or a pressure-based flow controller. The gas supply unit 510 may further include one or more flow rate modulators that supply one or more heat transfer medium generation gases at a modulated flow rate or in a pulsed manner.

The heat transfer medium generation gas supplied from the gas supply unit 510 is cooled in the channel 502 by, for example, the lower electrode 103J cooled by a temperature adjusting fluid in the channel 108, liquefies or solidifies, and then turns into a heat transfer medium including at least one of a liquid medium or a solid medium with fluidity.

As described above, the heat transfer medium is supplied to the ring support surface 104J₂ by, for example, capillary action, through the supply ports 500 to form the heat transfer layer DA for the edge ring E. The gas supply unit 510 may thus serve as at least a part of a heat transfer layer formation unit to form the heat transfer layer DA on the ring support surface 104J₂.

### Wafer Processing in Processing Module 60J

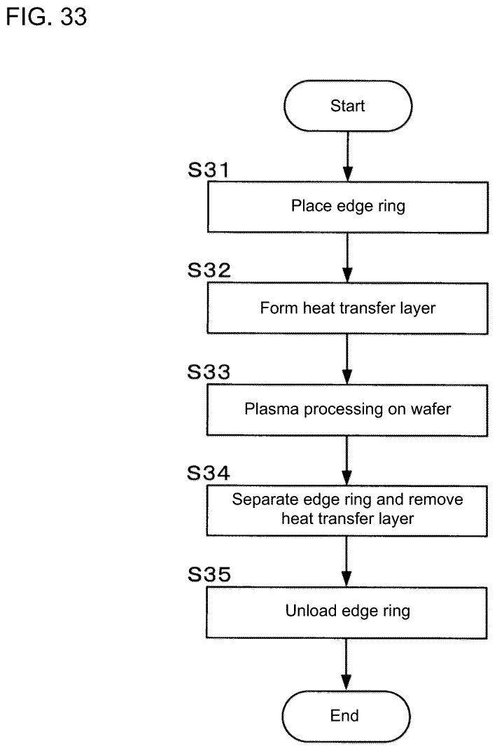

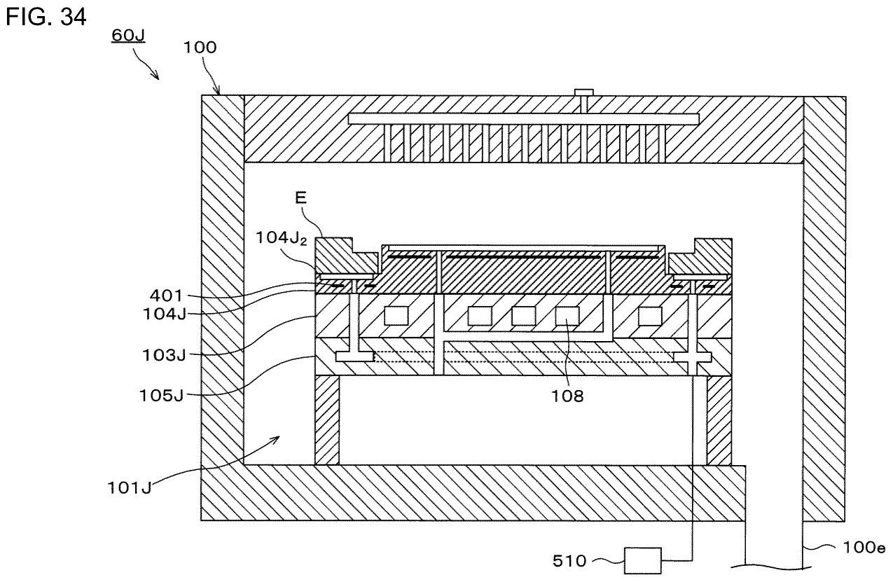

Example wafer processing including a process of replacing the edge ring E and performed in the processing module 60J will now be described with reference to FIGS. 33 to 36. FIG. 33 is a flowchart of example wafer processing. FIGS. 34 to 36 are each a diagram of the processing module 60J in a processing state during the wafer processing. The processing described below is performed under the control of the controller 80.

As shown in, for example, FIGS. 33 and 34, an edge ring E is placed onto the ring support surface 104J₂ of the wafer support 101J (step S31).

More specifically, the edge ring E is loaded into the plasma processing chamber 100 by the transferer 70, and is placed onto the ring support surface 104J₂ of the ESC 104J by using the lifters 400 that can ascend or descend. The internal space of the plasma processing chamber 100 is then decompressed to a predetermined degree of vacuum (pressure p11) by the exhaust system 150.

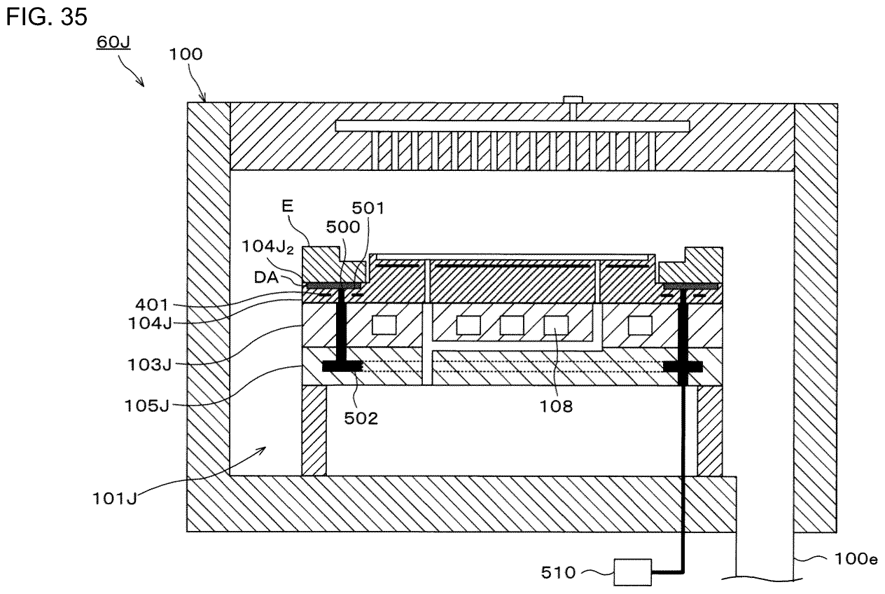

As shown in FIG. 35, the heat transfer medium including at least one of a liquid medium or a solid medium with fluidity is then supplied to between the ring support surface 104J₂ and the back surface of the edge ring E through the wafer support 101J to form the heat transfer layer DA (step S32).

More specifically, the edge ring E is held on the wafer support 101J. For example, a DC voltage may be applied to the electrode 401 of the ESC 104J, and the edge ring E is electrostatically clamped onto the ESC 104J with an electrostatic force. In this case, the temperature of the ring support surface 104J₂ is adjusted to a temperature T11, and the temperature in the channel 502 is adjusted to the temperature T11 accordingly. The temperature T11 is set to a temperature at which the processing can be performed effectively. The temperature T11 may be, for example, equal to the temperature of the ring support surface 104J₂ during the processing.

After the edge ring E is held on the wafer support 101J, the heat transfer medium generation gas is supplied from the gas supply unit 510 to the channel 502 in the wafer support 101J at a temperature T12 (>T11) and a pressure p12 (>p11). The heat transfer medium generation gas supplied to the channel 502 is cooled to the temperature T11 in the channel 502, and turns into a heat transfer medium including at least one of a liquid medium or a solid medium with fluidity. The heat transfer medium is then supplied to the ring support surface 104J₂ by, for example, capillary action, through the supply ports 500. The heat transfer medium supplied to the ring support surface 104J₂ spreads along the ring support surface 104J₂ by capillary action, which results from a clearance between the ring support surface 104J₂ and the back surface of the edge ring E. This forms the heat transfer layer DA.

As described above, the grooves 501 on the ring support surface 104J₂ widen the clearance between the ring support surface 104J₂ and the back surface of the edge ring E. This allows the heat transfer medium to spread appropriately along the ring support surface 104J₂ by capillary action.

A pressure p13 applied to the heat transfer layer DA is 0.1 to 100 Torr, including the pressure applied to the heat transfer layer DA by electrostatically clamping the edge ring E.

The supply of the heat transfer medium to the ring support surface 104J₂ (more specifically, the supply of the heat transfer medium generation gas from the gas supply unit 510) is stopped when, for example, the supply amount reaches a predetermined amount (more specifically, when the supply time of the heat transfer medium generation gas from the gas supply unit 510 exceeds a predetermined time). For example, a monitor such as a camera may be used to monitor leakage of the heat transfer medium from between the ring support surface 104J₂ and the back surface of the edge ring E. When leakage is detected, the supply of the heat transfer medium to the ring support surface 104J₂ may be stopped.

Plasma processing is then performed on the wafer W on the upper surface, or the support surface, of the ESC 104 on which the heat transfer layer DA is formed (step S33).

More specifically, for example, plasma processing is performed in the same manner as the processing described with reference to FIG. 3 and other figures. More specifically, for example, after the wafer W is placed on the wafer support surface 104₁ of the wafer support 101J and the heat transfer layer D is formed between the wafer support surface 104₁ and the back surface of the wafer W, plasma processing is then performed on the wafer W. The heat transfer layer D is then vaporized and removed, and the wafer W is unloaded.

During plasma processing, the ring support surface 104J₂ is adjusted to the predetermined temperature T11 with the temperature adjusting fluid flowing through the channel 108 to adjust the temperature of the edge ring E. During plasma processing, the edge ring E is placed on the ring support surface 104J₂ with the heat transfer layer DA in between. The heat transfer layer DA is deformable, allowing the lower surface, or the back surface, of the edge ring E to be in close contact with the heat transfer layer DA. The heat transfer layer DA is formed from the heat transfer medium including at least one of a liquid medium or a solid medium with fluidity. The heat transfer layer DA thus has higher thermal conductivity than a heat transfer gas, such as He. With the heat transfer layer DA, the temperature of the edge ring E can be adjusted more efficiently through the ring support surface 104J₂ than when a heat transfer gas, such as He, is supplied to between the ring support 104J₂ and the back surface of the edge ring E. More specifically, when a large amount of heat is input from the plasma P to the edge ring E during plasma processing, the edge ring E can be maintained at a constant temperature by adjusting the temperature of the ring support surface 104J₂. When the set temperature of the edge ring E is changed during plasma processing, the temperature of the edge ring E can be immediately adjusted to the changed set temperature by adjusting the temperature of the ring support surface 104J₂.

During plasma processing, a DC voltage is still applied to the electrode 401 in the ESC 104J to electrostatically clamp the edge ring E with the ESC 104J. The degree of contact of the edge ring E with the wafer support 101J may be controlled using an electrostatic force to control heat removal from the edge ring E through the wafer support 101J.

After plasma processing on the wafer W, the edge ring E is separated from the ring support surface 104J₂, and the heat transfer layer DA is vaporized and removed (step S34). In one example, the heat transfer layer DA is removed through vaporization. The separation of the edge ring E from the ring support surface 104J₂, or the removal of the edge ring E, may not be performed every time when plasma processing is performed on the wafer W, but may be performed when the edge ring E is worn or when the heat transfer layer DA is damaged or worn by plasma.

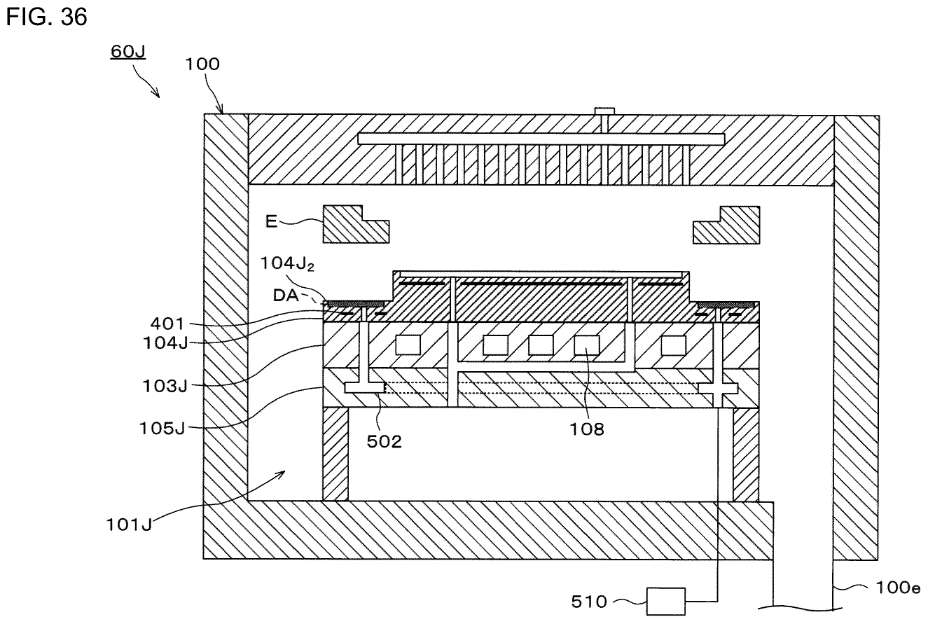

In step S34, more specifically, after the holding of the edge ring E on the wafer support 101J is stopped, or in other words, after the electrostatic clamping of the edge ring E with the ESC 104J is stopped, the edge ring E is raised by the lifters 400 to be separate from the ring support 104J₂, as shown in FIG. 36. Once the edge ring E is separated, the heat transfer layer DA is exposed to a decompressed atmosphere, or more specifically, to an atmosphere with the pressure p11 of less than 0.001 Torr, thus being vaporized and removed.

At least one of plasma, heat, or light may be used to remove the heat transfer layer DA from the ring support surface 104J₂, in place of or in addition to exposure to a decompressed atmosphere.

The heat transfer medium generation gas for the heat transfer layer DA may be the same as or different from that for the heat transfer layer D.

The edge ring E is then unloaded (step S35).

More specifically, the edge ring E is transferred from the lifters 400 to the transferer 70, and is unloaded from the plasma processing chamber 100 by the transferer 70.

The processing then returns to step S31, and step S32 is performed to place a new edge ring E onto the ring support surface 104J₂, and the heat transfer layer DA is formed on the ring support surface 104J₂.

### Advantageous Effects and Others

In the present embodiment, as described above, the heat transfer medium including at least one of a liquid medium or a solid medium with fluidity is supplied to between the ring support surface 104J₂ and the back surface of the edge ring E through the wafer support 101J to form the heat transfer layer DA. In the present embodiment, the temperature of the edge ring E is efficiently adjustable through the ring support surface 104J₂ during plasma processing, as in the second embodiment. The above heat transfer medium is less likely to clog the channel 502. No step for removing the heat transfer layer DA is used separately, improving throughput.

### Modifications of Sixth Embodiment

In the present embodiment as well, as in the modifications in the fifth embodiment described above, the edge ring E alone, of the wafer W and the edge ring E, may undergo temperature adjustment through the wafer support 101J and the heat transfer layer D. More specifically, the processing module 60J in the examples in FIGS. 31 and 32 includes both the channel 502 for forming the heat transfer layer DA for the edge ring E and the channel 310 for forming the heat transfer layer D for the wafer W. In some embodiments, the channel 310 may be eliminated.

In the present embodiment as well, as in the modifications in the fifth embodiment described above, the heat transfer layer D for the wafer W may be formed at the same time as the heat transfer layer DA for the edge ring E.

The heat transfer medium to form the heat transfer layer DA for the edge ring E may be supplied in any manner other than in the above example. Modifications similar to those in supplying the heat transfer medium to form the heat transfer layer D for the wafer W described above may be applied.

The heat transfer medium to form the heat transfer layer DA for the edge ring E may be any medium other than in the above example. Modifications similar to those in the heat transfer medium to form the heat transfer layer D for the wafer W described above may be applied.

A specific example similar to the grooves 320 for forming the heat transfer layer D for the wafer described above may be used for the grooves 501 for forming the heat transfer layer DA for the edge ring E.

Similarly to the wafer support surface, the ring support surface may have portions formed from a porous material located other than the grooves 501 (more specifically, for example, the top of the support posts in the grooves 501). When the grooves 501 are not located on the ring support surface, the ring support surface may be entirely formed from the porous material.

When the grooves 501 are not located on the ring support surface 104J₂ and the surface is entirely formed from the porous material, the porous material may have different thicknesses in different areas on the ring support surface 104J₂.

The heat transfer layer DA for the edge ring E may be formed from a conductive medium with high thermal conductivity and a conductive medium with low thermal conductivity mixed together. In this case, the mixing ratio of these conductive media may be different in different areas on the ring support surface 104J₂.

The density of the grooves 501 may be different in different areas on the ring support surface 104J₂.

In the above example, when the heat transfer layer DA for the edge ring E is removed from the ring support surface 104J₂ and the heat transfer layer DA is formed on the ring support surface 104J₂, the edge ring E is also replaced. In some embodiments, the edge ring may not be replaced. When not replaced, the edge ring E supported by the lifters 400 to be separate from the ring support surface 104J₂ for removing the heat transfer layer DA may be unloaded from the plasma processing chamber 100 and then reloaded into the plasma processing chamber 100, or the edge ring E may be placed on the ring support surface 104J₂ again without being unloaded.

### Modifications of Fifth and Sixth Embodiments

In the above example, an ESC is used as a fastener that holds or fastens the edge ring E on the ring support surface. The ESC electrostatically clamps the edge ring E with an electrostatic force generated by a DC voltage applied to the internal electrode 401.

The electrical fastener may not use an electrostatic force. In some embodiments, the fastener may hold the edge ring E with a Johnsen-Rahbek force.

The above fastener may hold the wafer W in any manner other than the electrical manner described above. For example, the above fastener may be a fastener, such as a clamp, to physically hold the wafer W.

The above fastener may be eliminated.

In the above example, the edge ring E is stored in the storage module 62 connected to the transfer module 50. In some embodiments, the edge ring E may be stored in the FOUP located on the load port 32, similarly to the wafer W.

A cover ring may be located on the wafer support in the processing module used for performing plasma processing. The cover ring covers the outer surface of the edge ring. In this case, a heat transfer layer may be formed on the support surface on which the cover ring is placed on the wafer support in the same manner as the heat transfer layer DA for the edge ring E described above.

### Other Modifications

The above removal of the heat transfer layer formed in on the different portions may be combined. To remove the heat transfer layer formed on the portions other than the wafer support surface, for example, two or more of plasma processing, heating, light irradiation, or decompressing the plasma processing chamber 100 may be used with the wafer W being held on the wafer support surface.

In the above example, plasma etching is performed as the plasma processing. However, the technique according to one or more embodiments of the present disclosure may be applied to processing other than etching (e.g., film deposition) as the plasma processing.

The embodiments disclosed herein are illustrative in all aspects and should not be construed to be restrictive. The components in the above embodiments may be eliminated, substituted, or modified in various forms without departing from the spirit and scope of the appended claims. For example, the components in the above embodiments may be combined as appropriate. These combinations produce the same advantageous effects as the respective embodiments in the combinations, as well as other advantageous effects that are apparent to those skilled in the art from the embodiments described herein.

The effects described herein are merely illustrative or exemplary and are not limitative. In other words, the technique according to one or more embodiments of the present disclosure may produce other effects that will be apparent to those skilled in the art from the embodiments described herein, in addition to or in place of the above effects.

The example structures described below may also fall within the technical scope of the present disclosure.
(1) A processing method for performing plasma processing on a substrate, the method comprising:
   placing a temperature adjustment target onto a support surface of a substrate support in a processing chamber being decompressible;
   forming a heat transfer layer for the temperature adjustment target on the support surface of the substrate support, the heat transfer layer being deformable and including at least one of a liquid layer or a deformable solid layer; and
   performing plasma processing on the substrate on the support surface on which the heat transfer layer is formed.
(2) The processing method according to (1), wherein
the forming the heat transfer layer includes supplying a raw gas being a raw material for the heat transfer layer into a processing space in the processing chamber.
(3) The processing method according to (2), wherein
the processing chamber includes a wall defining the processing space, and
the supplying the raw gas includes supplying the raw gas through the wall.
(4) The processing method according to (2) or (3), wherein the supplying the raw gas includes supplying the raw gas through the substrate support.
(5) The processing method according to any one of (2) to (4), wherein
the supplying the raw gas includes supplying the raw gas through a transferer configured to transfer the substrate to the processing chamber.
(6) The processing method according to any one of (2) to (5), wherein
the forming the heat transfer layer includes forming the heat transfer layer from the raw gas using plasma.
(7) The processing method according to any one of (2) to (5), wherein
the forming the heat transfer layer includes forming the heat transfer layer from the raw gas being at least liquefying or solidifying on the support surface being cooled.
(8) The processing method according to (1), wherein
the forming the heat transfer layer includes supplying a heat transfer medium including at least one of a liquid medium or a solid medium with fluidity to the support surface through the substrate support.
(9) The processing method according to any one of (1) to (8), wherein
the forming the heat transfer layer includes forming the heat transfer layer on the support surface by placing, in the placing the temperature adjustment target, the temperature adjustment target receiving, on a lower surface of the temperature adjustment target, the heat transfer layer onto the support surface.
(10) The processing method according to any one of (1) to (9), wherein
the forming the heat transfer layer includes forming the heat transfer layer on the support surface with the temperature adjustment target being located in the processing chamber and being separate from the support surface.
(11) The processing method according to any one of (1) to (8) and (10), wherein
the forming the heat transfer layer is performed before the placing the temperature adjustment target.
(12) The processing method according to (1) or (8), wherein
the forming the heat transfer layer is performed after the placing the temperature adjustment target.
(13) The processing method according to any one of (1) to (12), further comprising:
removing the heat transfer layer formed, in the forming the heat transfer layer, on a portion in the processing chamber other than the support surface.
(14) The processing method according to any one of (1) to (13), further comprising:
removing the heat transfer layer from the support surface after the performing plasma processing.
(15) The processing method according to (14), wherein
the removing the heat transfer layer from the support surface includes heating the support surface to vaporize the heat transfer layer.
(16) The processing method according to (14), wherein
the removing the heat transfer layer from the support surface includes removing the heat transfer layer using plasma.
(17) The processing method according to any one of (1) to (16), further comprising:
electrostatically clamping the temperature adjustment target onto the support surface with an electrostatic force from an electrostatic chuck.
(18) The processing method according to any one of (1) to (17), wherein
the temperature adjustment target is at least one of the substrate or an edge ring surrounding the substrate on the support surface.
(19) A plasma processing apparatus, comprising:
a processing chamber being decompressible;
a substrate support located in the processing chamber and including a support surface on which a substrate is placeable;
a heat transfer layer formation unit configured to form a heat transfer layer for the temperature adjustment target on the support surface of the substrate support, the heat transfer layer being deformable and including at least one of a liquid layer or a deformable solid layer; and
a controller configured to perform control to cause operations including
   placing the temperature adjustment target onto the support surface, and
   performing plasma processing on the substrate on the support surface on which the heat transfer layer is formed.
(20) The plasma processing apparatus according to (19), wherein
the heat transfer layer formation unit supplies a raw gas being a raw material for the heat transfer layer into a processing space in the processing chamber.
(21) The plasma processing apparatus according to (19) or (20), wherein
the heat transfer layer formation unit supplies a heat transfer medium including at least one of a liquid medium or a solid medium with fluidity to the support surface through the substrate support to form the heat transfer layer.
(22) The plasma processing apparatus according to any one of (19) to (21), wherein
the heat transfer layer formation unit places, onto the support surface, the temperature adjustment target receiving the heat transfer layer on a lower surface of the temperature adjustment target to form the heat transfer layer on the support surface.
(23) The plasma processing apparatus according to any one of (19) to (22), wherein
the heat transfer layer formation unit forms the heat transfer layer on the support surface with the temperature adjustment target being located in the processing chamber and being separate from the support surface.
(24) The plasma processing apparatus according to any one of (19) to (23), wherein
the temperature adjustment target is at least one of the substrate or an edge ring surrounding the substrate on the support surface.
(25) The plasma processing apparatus according to any one of (19) to (24), wherein
the substrate support includes an electrostatic chuck, and
the controller performs control to electrostatically clamp the temperature adjustment target onto the support surface with an electrostatic force from the electrostatic chuck.

### REFERENCE SIGNS LIST

60, 60E, 60F, 60G, 60H, 60J Processing module
80 Controller
100, 100A Plasma processing chamber
100s Plasma processing space
101, 101B, 101E, 101H, 101J Wafer support
1041, 104B1, 104E1 Wafer support surface
104H2, 104H2 Ring support surface
107C Lifter
400 Lifter
130, 130A, 130B, 130E, 510 Gas supply unit
D, DA Heat transfer layer
E Edge ring
W Wafer

1. A processing method for performing plasma processing on a substrate, the method comprising:
placing a temperature adjustment target onto a support surface of a substrate support in a processing chamber being decompressible;
forming a heat transfer layer for the temperature adjustment target on the support surface of the substrate support, the heat transfer layer being deformable and including at least one of a liquid layer or a deformable solid layer; and
performing plasma processing on the substrate on the support surface on which the heat transfer layer is formed.

2. The processing method according to claim 1, wherein
the forming the heat transfer layer includes supplying a raw gas being a raw material for the heat transfer layer into a processing space in the processing chamber.

3. The processing method according to claim 2, wherein
the processing chamber includes a wall defining the processing space, and
the supplying the raw gas includes supplying the raw gas through the wall.

4. The processing method according to claim 2, wherein
the supplying the raw gas includes supplying the raw gas through the substrate support.

5. The processing method according to claim 2, wherein
the supplying the raw gas includes supplying the raw gas through a transferer configured to transfer the substrate to the processing chamber.

6. The processing method according to claim 5, wherein
the forming the heat transfer layer includes forming the heat transfer layer from the raw gas using plasma.

7. The processing method according to claim 5, wherein
the forming the heat transfer layer includes forming the heat transfer layer from the raw gas being at least liquefying or solidifying on the support surface being cooled.

8. The processing method according to claim 1, wherein
the forming the heat transfer layer includes supplying a heat transfer medium including at least one of a liquid medium or a solid medium with fluidity to the support surface through the substrate support.

9. The processing method according to claim 5, wherein
the forming the heat transfer layer includes forming the heat transfer layer on the support surface by placing, in the placing the temperature adjustment target, the temperature adjustment target receiving, on a lower surface of the temperature adjustment target, the heat transfer layer onto the support surface.

10. The processing method according to claim 5, wherein
the forming the heat transfer layer includes forming the heat transfer layer on the support surface with the temperature adjustment target being located in the processing chamber and being separate from the support surface.

11. The processing method according to claim 5, wherein
the forming the heat transfer layer is performed before the placing the temperature adjustment target.

12. The processing method according to claim 8, wherein
the forming the heat transfer layer is performed after the placing the temperature adjustment target.

13. The processing method according to claim 5, further comprising:
removing the heat transfer layer formed, in the forming the heat transfer layer, on a portion in the processing chamber other than the support surface.

14. The processing method according to claim 5, further comprising:
removing the heat transfer layer from the support surface after the performing plasma processing.

15. The processing method according to claim 14, wherein
the removing the heat transfer layer from the support surface includes heating the support surface to vaporize the heat transfer layer.

16. The processing method according to claim 14, wherein
the removing the heat transfer layer from the support surface includes removing the heat transfer layer using plasma.

17. The processing method according to claim 5, further comprising:
electrostatically clamping the temperature adjustment target onto the support surface with an electrostatic force from an electrostatic chuck.

18. The processing method according to claim 5, wherein
the temperature adjustment target is at least one of the substrate or an edge ring surrounding the substrate on the support surface.

19. A plasma processing apparatus, comprising:
a processing chamber being decompressible;
a substrate support located in the processing chamber and including a support surface on which a substrate is placeable;
a heat transfer layer formation unit configured to form a heat transfer layer for the temperature adjustment target on the support surface of the substrate support, the heat transfer layer being deformable and including at least one of a liquid layer or a deformable solid layer; and
a controller configured to perform control to cause operations including
placing the temperature adjustment target onto the support surface, and
performing plasma processing on the substrate on the support surface on which the heat transfer layer is formed.

20. The plasma processing apparatus according to claim 19, wherein
the heat transfer layer formation unit supplies a raw gas being a raw material for the heat transfer layer into a processing space in the processing chamber.

21. The plasma processing apparatus according to claim 19, wherein
the heat transfer layer formation unit supplies a heat transfer medium including at least one of a liquid medium or a solid medium with fluidity to the support surface through the substrate support to form the heat transfer layer.

22. The plasma processing apparatus according to claim 19, wherein
the heat transfer layer formation unit places, onto the support surface, the temperature adjustment target receiving the heat transfer layer on a lower surface of the temperature adjustment target to form the heat transfer layer on the support surface.

23. The plasma processing apparatus according to claim 22, wherein
the heat transfer layer formation unit forms the heat transfer layer on the support surface with the temperature adjustment target being located in the processing chamber and being separate from the support surface.

24. The plasma processing apparatus according to claim 22, wherein
the temperature adjustment target is at least one of the substrate or an edge ring surrounding the substrate on the support surface.

25. The plasma processing apparatus according to claim 22, wherein
the substrate support includes an electrostatic chuck, and
the controller performs control to electrostatically clamp the temperature adjustment target onto the support surface with an electrostatic force from the electrostatic chuck.
